(19) United States
(12) Patent Application Publication
(10) Pub. No.: US 2026/0006963 A1
(43) Pub. Date: Jan. 1, 2026

(54) DISPLAY DEVICE AND METHOD FOR FABRICATING THE SAME

(71) Applicant: Samsung Display Co., LTD., Yongin-si (KR)

(72) Inventors: Sang Hyung LIM, Yongin-si (KR); In Hyuk KIM, Yongin-si (KR); Hyeong Su CHOI, Yongin-si (KR); Sang Wook HAN, Yongin-si (KR)

(73) Assignee: Samsung Display Co., LTD., Yongin-si (KR)

(21) Appl. No.: 19/189,786

(22) Filed: Apr. 25, 2025

(30) Foreign Application Priority Data
Jun. 26, 2024 (KR) 10-2024-0083403
Sep. 13, 2024 (KR) 10-2024-0125872

(51) Int. Cl. H10H 29/39; H10H 29/01; H10H 29/80

(52) U.S. Cl. CPC H10H 29/39; H10H 29/012; H10H 29/8325; H10H 29/842

(57) ABSTRACT

Provided is a display device including a lower substrate, a bonding electrode disposed on the lower substrate, a reflective electrode disposed on the bonding electrode, and a light-emitting element disposed on the reflective electrode, wherein the reflective electrode includes a reflective layer disposed between the bonding electrode and the light-emitting element and having a shape corresponding to that of the light-emitting element in a plan view, and a capping film covering a side surface of the reflective layer.

### CROSS-REFERENCE TO RELATED APPLICATION(S)

This application claims priority to and benefits of Korean Patent Application No. 10-2024-0083403 under 35 U.S.C. § 119, filed on Jun. 26, 2024, and Korean Patent Application No. 10-2024-0125872 under 35 U.S.C. § 119, filed on Sep. 13, 2024, in the Korean Intellectual Property Office, the entire contents of which are incorporated herein by reference.

### BACKGROUND

### 1. Technical Field

The disclosure relates to a display device, and a method of fabricating the display device.

### 2. Description of the Related Art

As the information-oriented society evolves, various demands for display devices are ever increasing. Accordingly, a variety of types of display devices, including light-emitting display devices, are under development. A light-emitting display device includes pixels including light-emitting elements.

### SUMMARY

Aspects of the disclosure provide a display device that may prevent short-circuit defects, and a method for fabricating a display device.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a display device including a lower substrate, a bonding electrode disposed on the lower substrate, a reflective electrode disposed on the bonding electrode, and a light-emitting element disposed on the reflective electrode, wherein the reflective electrode includes a reflective layer disposed between the bonding electrode and the light-emitting element and having a shape corresponding to a shape of the light-emitting element in a plan view, and a capping film covering a side surface of the reflective layer.

The capping film may be disposed along a border of the reflective layer and may cover the side surface of the reflective layer.

The reflective layer may include aluminum, and the capping film may include aluminum oxide.

The bonding electrode may have a size larger than a size of the reflective electrode in the plan view and may protrude outward from the reflective electrode.

The bonding electrode may have a cross section in an inverted taper shape.

The bonding electrode may include a bonding layer including a bonding metal, a first barrier layer covering a lower surface of the bonding layer, and a second barrier layer covering an upper surface of the bonding layer.

The bonding layer may include an alloy of gold and tin.

The second barrier layer may have a size larger than that of the bonding layer in the plan view and may protrude outward from the bonding layer.

The display device may further include an auxiliary layer disposed between the bonding electrode and the reflective electrode.

The auxiliary layer may have a size larger than that of the bonding layer in the plan view and may protrude outward from the bonding layer.

The reflective electrode may further include a third barrier layer covering an upper surface of the reflective layer.

The display device may further include a protective film covering a side surface of the light-emitting element and a side surface of the reflective electrode.

The protective film may expose a side surface of the bonding electrode.

The display device may further include a first contact electrode disposed between the reflective electrode and the light-emitting element, and the first contact electrode may have a shape corresponding to a lower surface of the light-emitting element in the plan view.

The protective film may further cover a side surface of the first contact electrode.

The display device may further include a second contact electrode disposed on the light-emitting element, a first insulating layer disposed on the second contact electrode and including an opening exposing at least a portion of the second contact electrode, and a common electrode disposed on the first insulating layer and electrically connected to the second contact electrode.

According to an aspect of the disclosure, there is provided a method for fabricating a display device, the method including preparing a first substrate including a semiconductor circuit board and a first bonding material layer disposed on the semiconductor circuit board, preparing a second substrate including a semiconductor substrate, and an epi-layer, a reflective material layer and a second bonding material layer sequentially disposed on the semiconductor substrate in a thickness direction, bonding the first bonding material layer with the second bonding material layer to form a bonding layer, separating the semiconductor substrate from the epi-layer and forming a first insulating material layer on the epi-layer, etching the first insulating material layer to form a first insulating layer, forming a light-emitting element and a reflective layer by etching the epi-layer and the reflective material layer, forming a capping film covering a side surface of the reflective layer, forming a protective film covering the bonding layer, the capping film and the light-emitting element, etching the protective film and the bonding layer, and forming a common electrode on the light-emitting element.

The forming the capping film may include forming an oxide film on a side surface of the reflective layer exposed by etching the reflective material layer.

The forming the light-emitting element and the reflective layer may include etching the epi-layer and the reflective material layer into a shape corresponding to the first insulating layer using the first insulating layer as a mask.

The method may further include, between the etching the bonding layer and the forming the common electrode, forming a second insulating layer covering the bonding electrode and the protective film, and forming an opening in the first insulating layer and the second insulating layer above the light-emitting element, and the common electrode may be electrically connected to the light-emitting element inside the opening.

According to an aspect of the disclosure, there is provided an electronic device including a lower substrate; a bonding electrode disposed on the lower substrate; a reflective electrode disposed on the bonding electrode; and a light-emitting element disposed on the reflective electrode. The reflective electrode may include a reflective layer disposed between the bonding electrode and the light-emitting element and having a shape corresponding to a shape of the light-emitting element in a plan view; and a capping film covering a side surface of the reflective layer.

The capping film may be disposed along a border of the reflective layer and completely covers the side surface of the reflective layer.

The reflective layer may include aluminum, and the capping film includes aluminum oxide.

The bonding electrode may have a size larger than a size of the reflective electrode in the plan view and protrudes outward from the reflective electrode.

The bonding electrode may have a cross section in an inverted taper shape.

The bonding electrode may include a bonding layer having a bonding metal; a first barrier layer covering a lower surface of the bonding layer; and a second barrier layer covering an upper surface of the bonding layer.

The bonding layer may include an alloy of gold and tin.

The second barrier layer may have a size larger than a size of the bonding layer in the plan view and protrudes outward from the bonding layer.

The electronic device may be at least one of a smart watch, a mobile phone, a smartphone, a portable computer, a tablet personal computer (PC), a watch phone, an automotive display, a smart glass, a portable multimedia player (PMP), a navigation system, an ultra-mobile computer (UMPC), a head mounted display (HMD) device, a virtual reality (VR) device, a mixed reality (MR) device, and an augmented reality (AR) device.

According to the embodiments of the disclosure, it is possible to prevent or reduce short-circuit defects in a display device, which may occur during a pixel formation process. Accordingly, it is possible to prevent or reduce defects in the display device, and the yield may be improved.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of a display device according to an embodiment of the disclosure.

FIG. 2 is a schematic plan view showing a unit pixel according to an embodiment of the disclosure.

FIG. 3 is a schematic cross-sectional view showing the display panel according to the embodiment of the disclosure.

FIG. 4 is a schematic cross-sectional view showing an example of area A1 of FIG. 3.

FIG. 5 is a schematic cross-sectional view showing a display panel according to an embodiment of the disclosure.

FIG. 6 is a schematic cross-sectional view showing the display panel according to the embodiment of the disclosure.

FIG. 7 is a schematic cross-sectional view showing the display panel according to the embodiment of the disclosure.

FIGS. 8 to 11 are schematic perspective views showing a method for fabricating a display device according to an embodiment.

FIGS. 12 to 24 are schematic cross-sectional views showing a method of fabricating a display device according to an embodiment.

FIG. 25 is a schematic block diagram illustrating a display system according to an embodiment.

FIG. 26 is a schematic view showing an example of a smart watch including a display device according to an embodiment.

FIGS. 27 and 28 are schematic views showing an example of a head-mounted display device including a display device according to an embodiment.

FIG. 29 is a schematic view showing an example of a head-mounted display device including a display device according to an embodiment.

FIG. 30 is a schematic view showing an example of an instrument cluster and a center fascia for a vehicle which include display devices according to an embodiment.

FIG. 31 is a schematic view showing an example of a transparent display device including a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. For example, regions illustrated in the drawings may be schematic in nature and the shapes of these regions may not reflect actual shapes of regions of a device and, as such, are not necessarily intended to be limiting.

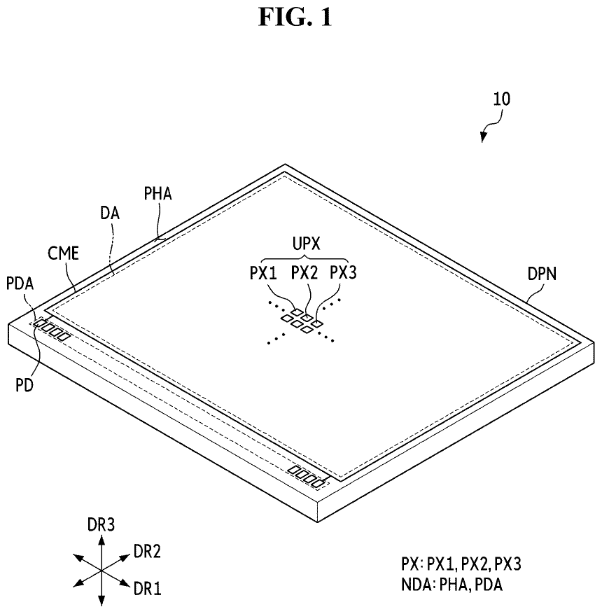

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts. FIG. 1 is a schematic perspective view of a display device according to an embodiment of the disclosure.

Referring to FIG. 1, a display device 10 displays moving images or still images and may be used as a display screen of a variety of electronic devices. For example, the display device 10 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of a variety of electronic devices such as a television, a notebook, a monitor, a billboard and the Internet of Things. The display device 10 may be applied to other electronic devices such as virtual reality (VR) devices and augmented reality (AR) devices. For example, the display device 10 may be included in at least one of the above-listed electronic devices, or may be included in other types of electronic devices.

The display device 10 may include a display panel DPN including a display area DA and a non-display area NDA.

The display panel DPN may have a rectangular shape having longer sides in the first direction DR1 and shorter sides in the second direction DR2 when viewed from a top (e.g., in a plan view). As depicted in FIG. 1, the first direction DR1 may refer to the horizontal direction of the display panel DPN, and the second direction DR2 may refer to the vertical direction of the display panel DPN. The third direction DR3 may refer to a thickness direction or a height direction of the display panel DPN. It should be understood, however, that the shape of the display panel DPN when viewed from a top (e.g., in a plan view) is not limited thereto. The display panel DPN may have other shapes. For example, the display panel DPN may have other polygonal shapes than a rectangle, a circular shape, an elliptical shape, or an irregular shape when viewed from a top (e.g., in a plan view).

In the display area DA, images may be displayed. In the non-display area NDA, images may not be displayed. The shape of the display area DA may follow the shape of the display panel DPN when viewed from a top (e.g., in a plan view). As depicted in FIG. 1, the display area DA has a rectangular shape when viewed from a top (e.g., in a plan view). The display area DA may be disposed at the center of display panel DPN. The non-display area NDA may be disposed around the display area DA. For example, the non-display area NDA may be disposed at the border of the display panel DPN to surround the display area DA.

The display panel DPN may include pixels PX arranged in the display area DA. For example, the display panel DPN may include first pixels PX1 that emit light of a first color, second pixels PX2 that emit light of a second color, and third pixels PX3 that emit light of a third color. The first color may be red, the second color may be green, and the third color may be blue. It is, however, to be understood that the disclosure is not limited thereto. At least one first pixel PX1, at least one second pixel PX2 and at least one third pixel PX3 adjacent to one another may form a unit pixel UPX capable of emitting light of various colors. For example, the first pixel PX1, the second pixel PX2 and the third pixel PX3 arranged sequentially or continuously in the first direction DR1 in the display area DA may form a single unit pixel UPX. The number, type, and/or arrangement structure of the pixels PX forming a unit pixel UPX may vary depending on embodiments.

The pixels PX may have, but is not limited to, a quadrangular shape when viewed from a top (e.g., in a plan view), such as a rectangle and a diamond. For example, the pixels PX may have other polygonal shapes (e.g., a hexagonal shape or a diamond shape), a circular shape, an elliptical shape, or other shapes when viewed from a top (e.g., in a plan view).

The pixels PX may be arranged in the display area DA in a matrix pattern, a stripe pattern, or other shapes. The sizes of the pixels PX may be equal to or different from one another.

The display device 10 may be a light-emitting display device including light-emitting elements. For example, each of the pixels PX of the display device 10 may include at least one light-emitting element.

The non-display area NDA may include a pad area PDA and a peripheral area PHA. The non-display area NDA may further include a common voltage supply area, etc., located around the display area DA. In the non-display area NDA, lines (or parts of the lines) electrically connected to the pixels PX and pads may be disposed. In the following description of the embodiments, the term “connection” may encompass electrical connection and/or physical connection.

The pads PD may be disposed in the pad area PDA. The pads PD may be electrically connected to an external circuit board. For example, the pads PD may be electrically connected to circuit pads on the circuit board through conductive connecting members such as wires. Driving signals and driving voltages for driving the pixels PX may be provided from the circuit board to the display device 10 through the pads PD.

The peripheral area PHA may be another area of the non-display area NDA than the pad area PDA. The peripheral area PHA may surround the display area DA.

The display device 10 may include a common electrode CME disposed across the entire display area DA. The common electrode CME may be electrically connected to at least one pad PD disposed in the pad area PDA and may receive a second driving voltage for driving the light-emitting elements through the pad. The second driving voltage may be a common voltage, such as a low-level pixel voltage and a cathode voltage. For example, the common electrode CME may be electrically connected to a plurality of pads PD arranged at the both ends of the pad area PDA, and may receive the common voltage from the circuit board through the plurality of pads PD. The shape, structure, and/or position of the common electrode CME are not limited to the embodiment of FIG. 1 and may vary depending on the embodiments. The display device 10 may further include an auxiliary line (e.g., an auxiliary line disposed in a mesh pattern in the display area DA so as to pass between the pixels PX) electrically connected to the common electrode CME.

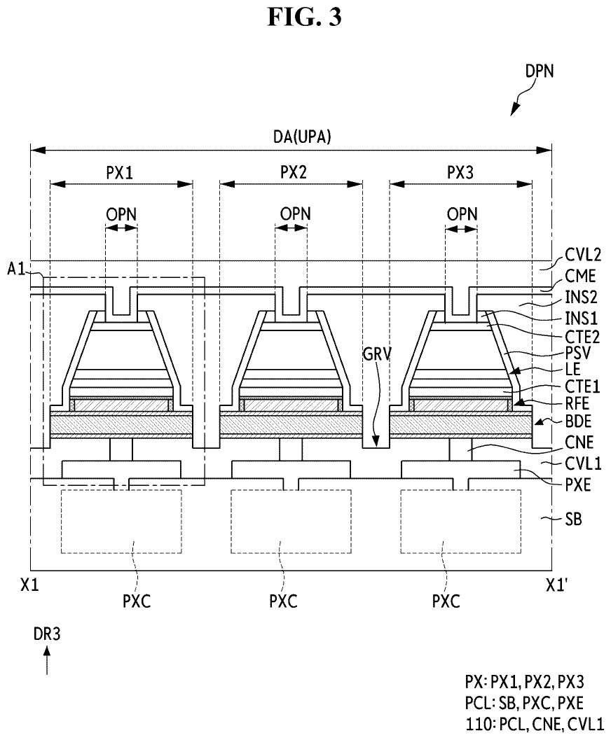

The pixels PX may receive the common voltage through the common electrode CME. The pixels PX may be electrically connected to other pads of the pad area PDA and/or a driver circuit. For example, the pixels PX may include circuit elements formed on a semiconductor circuit board, etc. (e.g., circuit elements forming the pixel circuit of each of the pixels PX), and may be electrically connected to other pads of the pad area PDA and/or a driver circuit through lines electrically connected to the circuit elements. The shape or position of the lines and/or electrodes (e.g., the common electrode CME) for providing driving signals and driving voltages to the pixels PX are not limited to the embodiments described above, and may be variously altered according to embodiments. According to an embodiment of the disclosure, at least a portion of the driver circuit may be disposed in the display panel DPN. For example, a part or all of the configurations of the driver circuit may be formed in the non-display area NDA of a lower substrate (e.g., the lower substrate 110 of FIG. 3) included in the display panel DPN. In other embodiments, the driver circuit may be disposed or provided outside the display panel DPN and electrically connected to a plurality of pads PD disposed in the pad area PDA.

The pixels PX may receive driving signals (e.g., a scan signal or a clock signal, and a data signal or digital data) and a first driving voltage from the other pads and/or the driver circuit. The first driving voltage may be a pixel voltage, like a high-level pixel voltage or an anode voltage. The pixels PX may emit light in response to driving signals and driving voltages (e.g., a first driving voltage and a second driving voltage).

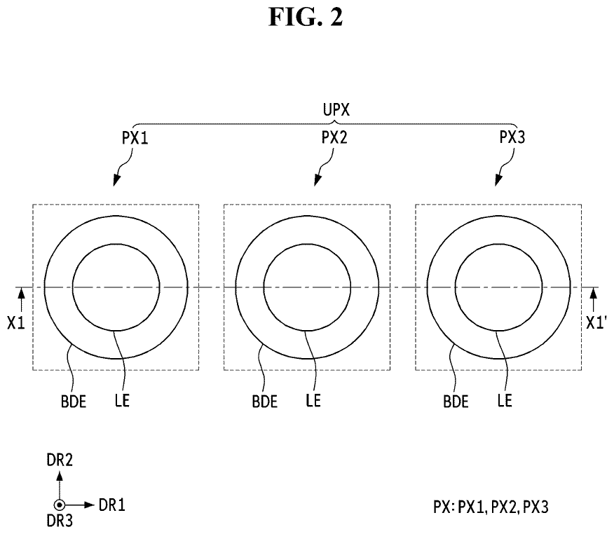

FIG. 2 is a schematic plan view showing a unit pixel according to an embodiment of the disclosure. For example, FIG. 2 schematically shows a shape of a unit pixel PX including a first pixel PX1, a second pixel PX2 and a third pixel PX3 when viewed from a top (e.g., in a plan view) as in the embodiment of FIG. 1.

Referring to FIGS. 1 and 2, each of the pixels PX may include a bonding electrode BDE and a light-emitting element LE disposed on the bonding electrode BDE. The bonding electrode BDE may be referred to as an electrode or a first electrode.

Although FIG. 2 discloses an embodiment in which each of the pixels PX includes a single light-emitting element LE, the embodiments of the disclosure are not limited thereto. For example, at least one of the first pixel PX1, the second pixel PX2 and the third pixel PX3 may include at least two light-emitting elements LE.

The bonding electrodes BDE may be disposed on a lower substrate (e.g., a lower substrate 110 of FIG. 3) including pixel circuits and lines. The bonding electrode BDE of each of the pixels PX may connect a pixel circuit (e.g., a pixel circuit PXC of FIG. 3) of a pixel PX with a light-emitting element LE. The bonding electrode BDE may have a size larger than the size of the light-emitting element LE when viewed from a top (e.g., in a plan view), and the light-emitting element LE may be disposed on a part of the bonding electrode BDE. The bonding electrodes BDE may have a circular shape, a rectangular shape, a polygonal shape other than a rectangular shape, or any other shape when viewed from a top (e.g., in a plan view). For example, the shape of the bonding electrodes BDE may be variously modified according to different embodiments.

The light-emitting elements LE may have a circular shape, a rectangular shape, a polygonal shape other than a rectangular shape, or any other shape when viewed from a top (e.g., in a plan view). For example, the shape of the light-emitting elements LE may be variously modified according to different embodiments.

The light-emitting elements LE may be micro light-emitting diodes (micro LEDs) having a small size in micrometers (μm). For example, each of the light-emitting elements LE may be a micro LED that has a length in the first direction DR1 (e.g., horizontal length), a length in the second direction DR2 (e.g., vertical length), and a length in the third direction DR3 (e.g., thickness or height) of about several micrometers (μm) to about hundreds of micrometers (μm). The length of each of the light-emitting elements LE in the first direction DR1, the length in the second direction DR2, and the length in the third direction DR3 may be equal to or less than about 100 μ. It should be understood, however, that the embodiments of the disclosure are not limited thereto.

The first pixels PX1, the second pixels PX2 and the third pixels PX3 may include the respective light-emitting elements LE that emit first color light, second color light, and third color light, respectively. In other embodiments, the first pixels PX1, the second pixels PX2, and the third pixels PX3 may include light-emitting elements LE that emit lights of the same color. In the emission areas of the first pixels PX1, the second pixels PX2 and/or the third pixels PX3, light conversion patterns (e.g., wavelength conversion patterns containing quantum dots) and/or color filters for converting the colors or wavelengths of lights emitted from the light-emitting elements LE disposed in each of the pixels PX may be disposed.

Each of the pixels PX may further include a reflective electrode (e.g., a reflective electrode RFE of FIG. 3) disposed below the light-emitting element LE. For example, each of the pixels PX may further include a reflective electrode disposed between the bonding electrode BDE and the light-emitting element LE. Although the reflective electrode and the bonding electrode BDE are described separately as individual elements in the following descriptions, the embodiments of the disclosure are not limited thereto. For example, the reflective electrode may be regarded as being included in the bonding electrode BDE.

The reflective electrode may have a shape and size corresponding to those of the light-emitting element LE. For example, the shape and size of the reflective electrode may correspond to (e.g., substantially the same as or similar to) the shape and size of the light-emitting element LE when viewed from a top (e.g., in a plan view). In each of the pixels PX, the reflective electrode may be disposed on at least a part of the bonding electrode BDE.

FIG. 3 is a schematic cross-sectional view showing the display panel according to the embodiment of the disclosure. For example, FIG. 3 shows an example of the cross section of the display panel DPN taken along line X1-X1′ of FIG. 2, specifically, a schematic cross-section of a first pixel PX1, a second pixel PX2, and a third pixel PX3 located in a unit pixel area UPA of the display area DA.

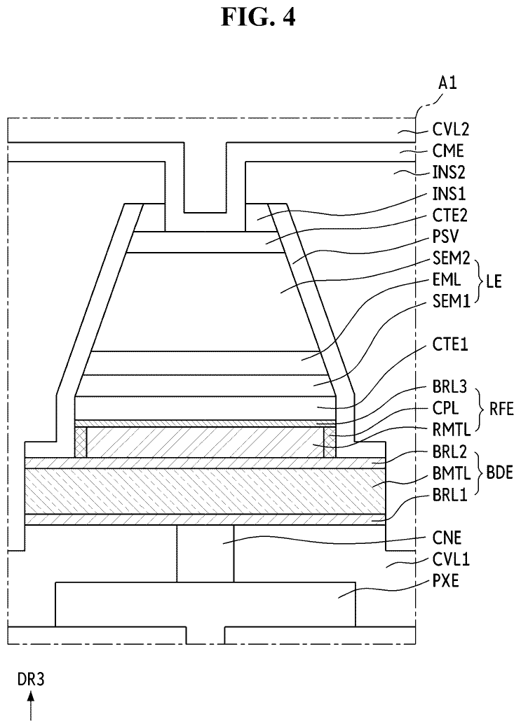

FIG. 4 is a schematic cross-sectional view showing an example of area A1 of FIG. 3. For example, FIG. 4 shows in detail the structure of a bonding electrode BDE and a reflective electrode RFE according to the embodiment.

As depicted in FIGS. 3 and 4, the display device 10 may be implemented as a light-emitting diode on silicon (LEDoS) display, in which light-emitting diodes are disposed as light-emitting elements LE on a semiconductor circuit substrate PCL formed via a semiconductor process using a silicon wafer. It should be understood, however, that the structure or type of devices in which the embodiments may be applied is not limited thereto. For example, the embodiments may be applied to a display device of a different type and/or structure, or may be applied to a device of a different type and/or structure, such as a luminaire.

Referring to FIGS. 1 to 4, the display panel DPN may include a semiconductor circuit board PCL (or a thin-film transistor substrate), connection electrodes CNE and a first passivation layer CVL1 disposed on the semiconductor circuit board PCL, bonding electrodes BDE disposed on the connection electrodes CNE and the first passivation layer CVL1, and reflective electrodes RFE and light-emitting elements LE disposed on the bonding electrodes BDE. The display panel DPN may further include at least one of: contact electrodes CTE1 and CTE2 disposed on at least a surface of the light-emitting elements LE, a protective film PSV surrounding the side surfaces of the light-emitting elements LE, a first insulating layer INS1 and a second insulating layer INS2 disposed in the vicinity of the light-emitting elements LE including the upper portions of the light-emitting elements LE, and a common electrode CME and a second passivation layer CVL2 disposed on the light-emitting elements LE, the first insulating layer INS1 and the second insulating layer INS2. The display panel DPN may further include an optical structure (e.g., a micro lens disposed on a light-emitting element LE of each of the pixels PX) disposed on the second passivation layer CVL2, etc.

In the following descriptions, the conductive elements containing a conductive material, e.g., the elements referred to by terms including “electrode” may also be referred to as “conductive layer,” “conductive film,” or “conductive pattern,” etc. Insulating elements containing an insulating material, e.g., the elements referred to by terms such as “insulating layer,” “protective film” and “passivation layer” may also be referred to as “insulating layer,” “insulating film,” or “insulating pattern.”

A semiconductor circuit board PCL may include the display area DA in which the pixel circuits PXC of the pixels PX are formed. The semiconductor circuit board PCL may further include the non-display area NDA of FIG. 1. For example, the semiconductor circuit board PCL may further include pads PD located in the non-display area NDA.

The semiconductor circuit board PCL may include a base substrate SB, pixel circuits PXC arranged or formed on the base substrate SB, and pixel electrodes PXE (or connection lines) electrically connected to each of the pixel circuits PXC. The semiconductor circuit board PCL may further include lines electrically connected to the pixels PX. For example, the semiconductor circuit board PCL may further include signal lines and power lines (e.g., a first power line and a second power line transmitting a first driving voltage and a second driving voltage, respectively) electrically connected to the pixel circuits PXC.

The semiconductor circuit board PCL may be formed by a semiconductor process using a silicon wafer. For example, the base substrate SB may be a silicon wafer. The base substrate SB may be made of monocrystalline silicon.

The pixel circuits PXC may be arranged on the semiconductor circuit board PCL in the respective pixel areas in which the pixels PX are arranged. Each of the pixel circuits PXC may include a complementary metal-oxide semiconductor (CMOS) circuit formed using a semiconductor process. Each of the pixel circuits PXC may include at least one transistor and at least one capacitor formed via a semiconductor process. FIG. 3 schematically shows the locations of the pixel circuits PXC included in the first pixel PX1, the second pixel PX2 and the third pixel PX3 as an example of elements disposed inside the semiconductor circuit board PCL.

The pixel electrodes PXE may be disposed on the respective pixel circuits PXC. The pixel electrodes PXE may be electrically connected to the respective pixel circuits PXC. For example, the pixel circuit PXC of each of the pixels PX may be electrically connected to the pixel electrode PXE of the respective pixels PX. The pixel electrodes PXE may receive a first driving voltage from the respective pixel circuits PXC.

The pixel electrodes PXE may be integrally formed with the respective pixel circuits PXC. For example, the pixel electrodes PXE may be electrodes (or contact terminals) that protrude and are exposed from the upper surfaces of the respective pixel circuits PXC.

The pixel electrodes PXE may include at least one conductive material. For example, the pixel electrodes PXE may include, but are not limited to, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or mixtures thereof.

The pixel electrodes PXE may be electrically connected to the light-emitting elements LE through the connection electrodes CNE and the bonding electrodes BDE, respectively. For example, the pixel electrode PXE of each of the pixels PX may be electrically connected to the light-emitting element LE on the bonding electrode BDE through the connection electrode CNE and the bonding electrode BDE of the respective pixels PX. At least one electrode may be further disposed between the bonding electrode BDE and the light-emitting element LE. The bonding electrode BDE and the light-emitting element LE may be electrically connected with each other via the at least one electrode. For example, a reflective electrode RFE, a first contact electrode CTE1, and a light-emitting element LE may be sequentially disposed on the bonding electrode BDE in the third direction DR3. The bonding electrode BDE may be electrically connected to the light-emitting element LE via the reflective electrode RFE and the first contact electrode CTE1.

A first passivation layer CVL1 may be disposed on the pixel circuits PXC and the pixel electrodes PXE. The first passivation layer CVL1 may cover a semiconductor circuit board PCL including a base substrate SB, the pixel circuits PXC and the pixel electrodes PXE.

The first passivation layer CVL1 may include openings (e.g., contact holes or via holes) that partially expose the pixel electrodes PXE. The openings may be filled with the connection electrodes CNE. For example, the first passivation layer CVL1 may surround the connection electrodes CNE.

The first passivation layer CVL1 may include grooves GRV etched between the pixels PX in the thickness direction. For example, in an etching process for forming the bonding electrodes BDE, the first passivation layer CVL1 may be etched to a certain thickness. As a result, the grooves GRV may be formed in the first passivation layer CVL1 at separation regions between the bonding electrodes BDE. By sufficiently etching the bonding electrodes BDE with a process margin sufficient to form the grooves GRV in the first passivation layer CVL1, the bonding electrodes BDE of the pixels PX may be stably separated.

The first passivation layer CVL1 may include at least one insulating material and may have a single-layer or multi-layer structure. The first passivation layer CVL1 may include, but is not limited to, an inorganic insulating material (e.g., silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or other inorganic insulating material).

The connection electrodes CNE may electrically connect the semiconductor circuit board PCL with the bonding electrodes BDE. For example, the connection electrodes CNE may be electrically connected between the pixel electrode PXE and the bonding electrode BDE of each of the pixels PX.

The connection electrodes CNE may include a conductive metal. For example, the connection electrodes CNE may include at least one of gold (Au), copper (Cu), tin (Sn), titanium (Ti), aluminum (Al) and silver (Ag).

The semiconductor circuit board PCL, the connection electrodes CNE, and the first passivation layer CVL1 may form a lower substrate 110 (e.g., a backplane substrate) of the display panel DPN. The bonding electrodes BDE, the reflective electrodes RFE, and the light-emitting elements LE, etc., may be disposed on the lower substrate 110.

The bonding electrodes BDE may be disposed on the first passivation layer CVL1. The bonding electrodes BDE may be separately disposed from each other in the respective pixel areas where the pixels PX are arranged. Accordingly, the light-emitting elements LE of the pixels PX may be driven individually. Each of the bonding electrodes BDE may be electrically connected to the connection electrode CNE of the respective pixels PX. The bonding electrode BDE may work as an anode electrode of the light-emitting element LE or the pixel PX.

Each of the bonding electrodes BDE may be made up of a single layer or multiple layers including a bonding layer BMTL (also referred to as a bonding metal layer). For example, as shown in FIG. 4, each of the bonding electrodes BDE may include a bonding layer BMTL, and first and second barrier layers BRL1 and BRL2 disposed on the both surfaces of the bonding layer BMTL. According to an embodiment of the disclosure, each of the bonding electrodes BDE may further include an additional layer. For example, each of the bonding electrodes BDE may further include an adhesive layer disposed between the connection electrode CNE and the first barrier layer BRL1. The adhesive layer may include a material suitable for improving adhesion between the connection electrode CNE and the bonding electrode BDE.

The bonding layer BMTL may include a conductive material suitable for bonding, e.g., a bonding metal. For example, the bonding layer BMTL may include a metal or metal alloy having excellent electrical and thermal conductivity.

The bonding layer BMTL may have a thickness sufficient to perform the bonding process. For example, the bonding layer BMTL may have the largest thickness among the layers forming the bonding electrode BDE and the reflective electrode RFE. For example, the bonding layer BMTL may have, but is not limited to, a thickness of about several hundred nm (e.g., a thickness in the range of about 200 nm to about 500 nm).

The bonding layer BMTL may include an alloy of gold (Au) and tin (Sn). Since the alloy of Gold (Au) and tin (Sn) has excellent bonding strength and a low melting point, the temperature of the bonding process (e.g., a wafer-to-wafer bonding process using a bonding layer BMTL) may be lowered while the light-emitting elements LE (or an epi-layer formed with the light-emitting elements LE) may be bonded to the lower substrate 110. Accordingly, it is possible to prevent the light-emitting elements LE or the nearby elements from being damaged or deteriorated by the bonding process. The alloy of gold (Au) and tin (Sn) have low resistance changes with temperature and are electrically stable. Therefore, the pixel electrode PXE and the light-emitting element LE may be electrically and/or physically stably connected by the bonding layer BMTL including the alloy of gold (Au) and tin (Sn), and the reliability and operating characteristics of the light-emitting element LE and the pixel PX including the same may be improved. It should be noted that the material of the bonding layer BMTL is not limited to the alloy of gold (Au) and tin (Sn). For example, the bonding layer BMTL may include other highly reliable bonding metals, such as titanium (Ti), zirconium (Zr), nickel (Ni) and chromium (Cr).

The first barrier layer BRL1 may be disposed under the bonding layer BMTL. For example, the first barrier layer BRL1 may be disposed between the connection electrode CNE and the bonding layer BMTL and may cover the lower surface of the bonding layer BMTL.

The second barrier layer BRL2 may be disposed on the bonding layer BMTL. For example, the second barrier layer BRL2 may be disposed between the bonding layer BMTL and the reflective electrode RFE and may cover the upper surface of the bonding layer BMTL.

Each of the first barrier layer BRL1 and the second barrier layer BRL2 may include a material suitable for preventing diffusion (e.g., preventing diffusion between metals), and may include the same material or different materials. Each of the first barrier layer BRL1 and the second barrier layer BRL2 may be formed of a material and/or with a thickness capable of ensuring conductivity of the bonding electrode BDE. According to an embodiment of the disclosure, each of the first barrier layer BRL1 and the second barrier layer BRL2 may include a material that effectively prevents diffusion between metals, such as titanium (Ti), titanium nitride (TiN) and nickel (Ni), or other materials for preventing diffusion, and may be formed to a thickness less than or equal to the thickness of the reflective layer RMTL and/or the bonding layer BMTL. For example, each of the first barrier layer BRL1 and the second barrier layer BRL2 may include, but is not limited to, a material suitable for preventing diffusion between metals included in the bonding layer BMTL and/or the reflective layer RMTL, and may be formed to a thickness in the range of about 80 nm to about 120 nm.

According to the embodiment of the disclosure, a reflective electrode RFE and a first contact electrode CTE1 may be sequentially disposed on each of the bonding electrodes BDE, and the light-emitting element LE may be disposed on the first contact electrode CTE1. In other embodiments, the pixel PX may not include the first contact electrode CTE1, and the light-emitting element LE may be disposed (e.g., directly disposed) on the reflective electrode RFE.

As depicted in FIGS. 3 and 4, the reflective electrode RFE and the bonding electrode BDE have different sizes (e.g., different planar areas) in a plan view. Although the reflective electrode RFE is a separate element from the bonding electrode BDE as depicted in FIGS. 3 and 4, the embodiments of the disclosure are not limited thereto. For example, the reflective electrode RFE may be regarded as being included in the bonding electrode BDE.

The reflective electrode RFE and the bonding electrode BDE may be formed with different sizes by each of mask processes using different masks. For example, an etching process for etching the reflective electrode RFE may be performed first, and then an etching process for etching the bonding electrode BDE may be conducted.

For example, the reflective electrode RFE may have a smaller size than the bonding electrode BDE when viewed from a top (e.g., in a plan view) and may be disposed on a part of the bonding electrode BDE. The bonding electrode BDE may protrude outside the reflective electrode RFE when viewed from a top (e.g., in a plan view).

Although the first contact electrode CTE1 is depicted as a separate element from the light-emitting element LE as depicted in FIGS. 3 and 4, the embodiments of the disclosure are not limited thereto. For example, the first contact electrode CTE1 may be regarded as being included in the light-emitting element LE. The first contact electrode CTE1 may be formed or etched together with the light-emitting element LE, or may be formed or etched separately from the light-emitting element LE. The light-emitting element LE, the first contact electrode CTE1 and the reflective electrode RFE may be etched using the same mask, and may have sizes and/or shapes that correspond to one another when viewed from a top (e.g., in a plan view). For example, when viewed from a top (e.g., in a plan view), the light-emitting element LE, the first contact electrode CTE1 and the reflective electrode RFE may have substantially the same or similar areas and shapes when viewed from a top (e.g., in a plan view).

The reflective electrodes RFE may be disposed on the bonding electrodes BDE, respectively. Each of the reflective electrodes RFE may be made up of a single layer or multiple layers including a reflective layer RMTL (also referred to as a reflective electrode layer). For example, as shown in FIG. 4, each of the reflective electrodes RFE may include the reflective layer RMTL and a third barrier layer BRL3 disposed on the reflective layer RMTL. Each of the reflective electrodes RFE may further include a capping layer CPL disposed on side surfaces of the reflective layer RMTL.

The reflective layer RMTL may include a conductive material (e.g., a metal) having high light reflectance. For example, the reflective layer RMTL may include aluminum Al or may include other highly reflective metals (e.g., molybdenum (Mo), titanium (Ti), copper (Cu), silver (Ag), magnesium (Mg), platinum (Pt), palladium (Pd), gold (Au), nickel (Ni), neodymium (Nd), iridium (Ir), chromium (Cr), etc.). The reflective layer RMTL may be formed to a thickness suitable for ensuring or improving light reflectance (e.g., a thickness in the range of about 80 nm to about 200 nm).

The reflective layer RMTL may be disposed between the bonding electrode BDE and the light-emitting element LE, and the surface of the reflective layer RMTL may be covered with the second barrier layer BRL2, the third barrier layer BRL3 and the capping layer CPL. For example, the lower surface, the upper surface and the side surfaces of the reflective layer RMTL may be covered (e.g., completely covered) by the second barrier layer BRL2, the third barrier layer BRL3 and the capping layer CPL, respectively.

The reflective layer RMTL may have a shape and/or size corresponding to the shape and/or size of the light-emitting element LE when viewed from a top (e.g., in a plan view). For example, the light-emitting element LE and the reflective layer RMTL may be etched altogether by an etching process using the same mask. Accordingly, the lower surface of the light-emitting element LE and the reflective layer RMTL may have shapes and/or areas corresponding to one another (e.g., substantially the same) when viewed from a top (e.g., in a plan view).

The third barrier layer BRL3 may be disposed on the reflective layer RMTL. For example, the third barrier layer BRL3 may be disposed between the reflective layer RMTL and the first contact electrode CTE1 and may cover the upper surface of the reflective layer RMTL.

The third barrier layer BRL3 may include a material suitable for preventing diffusion (e.g., diffusion between metals) and may be formed with a material and/or thickness capable of ensuring conductivity of the reflective electrode RFE. The third barrier layer BRL3 may include titanium (Ti), titanium nitride (TiN), nickel (Ni), or other materials for preventing diffusion. For example, the third barrier layer BRL3 may include titanium nitride (TiN) and have a thickness of about 20 nm or less (e.g., a thickness of about 10 nm), and accordingly it may prevent diffusion of a metal included in the reflective layer RMTL while ensuring conductivity of the reflective electrode RFE.

The capping layer CPL may be disposed on the side surfaces of the reflective layer RMTL. For example, the capping layer CPL may be disposed along the border of the reflective layer RMTL and may cover (e.g., completely cover) the side surfaces of the reflective layer RMTL.

The capping layer CPL may be formed to cover the side surfaces of the reflective layer RMTL immediately after the reflective layer RMTL has been etched. It is possible to prevent by the capping layer CPL the material (e.g., aluminum (Al)) of the reflective layer RMTL from being eluted in a subsequent process (e.g., the process of etching the bonding electrode BDE) and to appropriately protect the reflective layer RMTL.

The capping film CPL may be formed by post-processing performed immediately after the etching of the reflective layer RMTL. For example, the capping film CPL may be formed immediately after the etching of the reflective layer RMTL using high-temperature (e.g., gaseous) H₂O and CH₄/O₂, or other post-processing materials. The capping film CPL may contain an oxide formed by the post-processing material. The reflective layer RMTL may include aluminum (Al), and the capping film CPL may include aluminum oxide (AlₓO_{y}) (e.g., Al₂O₃).

It should be noted that the material or method for forming the capping film CPL is not limited thereto. For example, the capping film CPL may be formed on the side surfaces of the reflective layer RMTL by a separate deposition process and/or etching process performed after etching the reflective layer RMTL and before etching the bonding layer BMTL. The material of the capping film CPL is not limited to aluminum oxide (AlₓO_{y}). For example, the capping film CPL may include silicon oxide (SiOₓ) (e.g., SiO₂), silicon nitride (SiNₓ) (e.g., Si₃N₄), titanium oxide (TiₓO_{y}) (e.g., TiO₂), hafnium oxide (HfOₓ), or other materials.

The first contact electrode CTE1 may be disposed on the reflective electrode RFE. For example, the first contact electrode CTE1 may be disposed between the reflective electrode RFE and the light-emitting element LE.

The first contact electrode CTE1 may be disposed on a surface (e.g., the lower surface) of the first semiconductor layer SEM1 included in the light-emitting element LE. The first contact electrode CTE1 may protect the first semiconductor layer SEM1 and stably connect the light-emitting element LE with the reflective electrode RFE.

The first contact electrode CTE1 may be disposed (e.g., entirely disposed) on the surface of the first semiconductor layer SEM1. For example, the first contact electrode CTE1 may be disposed (e.g., entirely disposed) on the lower surface of the first semiconductor layer SEM1. For example, the first semiconductor layer SEM1 may be appropriately or stably protected. It should be understood that the embodiments of the disclosure are not limited thereto. The first contact electrode CTE1 may be disposed only on a portion of the first semiconductor layer SEM1.

The first contact electrode CTE1 may have a size and/or shape corresponding to the lower surface of the light-emitting element LE when viewed from a top (e.g., in a plan view). For example, the light-emitting element LE and the first contact electrode CTE1 may be etched altogether by an etching process using the same mask. Accordingly, the lower surface of the light-emitting element LE and the first contact electrode CTE1 may have a shape and/or area corresponding to each other (e.g., substantially the same) when viewed from a top (e.g., in a plan view).

The first contact electrode CTE1 may include metal, metal oxide, or other conductive material. The first contact electrode CTE1 may be formed as a transparent electrode layer including a transparent conductive material (e.g., indium tin oxide (ITO), indium zinc oxide (IZO), or other transparent conductive material). The first contact electrode CTE1 may be formed as a thin film having a thickness of several tens of nanometers, for example, in the range of about 10 nm to about 50 nm. It should be noted that the material or thickness of the first contact electrode CTE1 is not limited thereto and may vary depending on embodiments.

Each of the light-emitting elements LE may be disposed on the first contact electrode CTE1 (or the reflective electrode RFE) of the respective pixels PX.

Each of the light-emitting elements LE may include a first semiconductor layer SEM1, an emissive layer EML, and a second semiconductor layer SEM2 sequentially disposed on the first contact electrode CTE1. For example, the first semiconductor layer SEM1, the emissive layer EML and the second semiconductor layer SEM2 may be sequentially disposed or stacked on the first contact electrode CTE1 in the third direction DR3. The first semiconductor layer SEM1, the emissive layer EML and the second semiconductor layer SEM2 may be formed from a semiconductor epitaxial stack or epi-layers formed by epitaxial growth on a semiconductor substrate.

The first semiconductor layer SEM1 may include a semiconductor material doped with a first conductivity type dopant. For example, the first semiconductor layer SEM1 may be a first-conductivity semiconductor layer including a nitride-based semiconductor material, a phosphide-based semiconductor material, or other semiconductor material, and further including a first-conductivity dopant. The first semiconductor layer SEM1 may be, but is not limited to, a p-type semiconductor layer (e.g., p-GaN) doped with a p-type dopant such as Mg, Zn, Ca, Se, and Ba.

The emissive layer EML may be disposed on the first semiconductor layer SEM1. For example, the emissive layer EML may be disposed between the first semiconductor layer SEM1 and the second semiconductor layer SEM2. The emissive layer EML may emit light as electron-hole pairs are recombined therein, which are generated in response to an electrical signal applied through the first semiconductor layer SEM1 and the second semiconductor layer SEM2.

The emissive layer EML may include a nitride-based semiconductor material, a phosphide-based semiconductor material, or other semiconductor material, and may have a single or multiple quantum well structure. The emissive layer EML may have, but is not limited to, a multi-quantum well structure including a quantum well layer including InGaN, and a barrier layer including GaN, AlGaN or GaAlN. According to an embodiment of the disclosure, if the emissive layer EML contains InGaN, the color of light emitted from the emissive layer EML may be adjusted or changed by adjusting the content of indium (In).

The emissive layer EML may emit light in a visible wavelength range, e.g., light in a wavelength range of about 400 nm to about 900 nm. For example, the emissive layer EML may emit blue light with a peak wavelength ranging from about 440 nm to about 480 nm, green light with a peak wavelength ranging from about 510 nm to about 550 nm, or red light with a peak wavelength ranging from about 610 nm to about 650 nm. The emissive layer EML may emit light of a color or wavelength other than those described above.

The second semiconductor layer SEM2 may include a semiconductor material doped with a second conductivity type dopant. For example, the second semiconductor layer SEM2 may be a second-conductivity semiconductor layer including a nitride-based semiconductor material, a phosphide-based semiconductor material, or other semiconductor material, and further including a second-conductivity dopant. The second semiconductor layer SEM2 may be, but is not limited to, an n-type semiconductor layer (e.g., n-GaN) doped with an n-type dopant such as Si, Ge, Sn, etc.

According to the embodiment of the disclosure, a second contact electrode CTE2 may be disposed on each of the light-emitting elements LE, and a common electrode CME may be disposed on the second contact electrode CTE2. For example, the second semiconductor layer SEM2 of the light-emitting element LE may be electrically connected to the common electrode CME via the second contact electrode CTE2.

Although the second contact electrode CTE2 is depicted as a separate element from the light-emitting element LE as depicted in FIGS. 3 and 4, the embodiments of the disclosure are not limited thereto. For example, the second contact electrode CTE2 may be regarded as being included in the light-emitting element LE. The second contact electrode CTE2 may be formed or etched together with the light-emitting element LE, or may be formed or separately etched from the light-emitting element LE.

In other embodiments, the light-emitting element LE or the pixel PX may not include the second contact electrode CTE2. For example, the common electrode CME may be directly connected or in contact with the light-emitting element LE.

The second contact electrode CTE2 may be disposed on a surface (e.g., the upper surface) of the second semiconductor layer SEM2. The second contact electrode CTE2 may protect the second semiconductor layer SEM2 and stably connect the light-emitting element LE with the common electrode CME.

The second contact electrode CTE2 may be disposed (e.g., entirely disposed) on the surface of the second semiconductor layer SEM2. For example, the second contact electrode CTE2 may be disposed (e.g., entirely disposed) on the upper surface of the second semiconductor layer SEM2. For example, the second semiconductor layer SEM2 may be stably protected. It should be understood that the embodiments of the disclosure are not limited thereto. The second contact electrode CTE2 may be disposed only on a portion of the second semiconductor layer SEM2.

The second contact electrode CTE2 may include metal, metal oxide, or other conductive material. The second contact electrode CTE2 may be formed as a transparent electrode layer including a transparent conductive material (e.g., indium tin oxide (ITO), indium zinc oxide (IZO), or other transparent conductive material). Accordingly, light generated from the light-emitting element LE may transmit the second contact electrode CTE2 and exit from the top of the light-emitting element LE.

According to the embodiment of the disclosure, a first insulating layer INS1 may be disposed on the second contact electrode CTE2. If each of the light-emitting element LE or the pixel PX does not include the second contact electrode CTE2, the first insulating layer INS1 may be disposed on each of the light-emitting element LE.

The first insulating layer INS1 may include an opening OPN exposing a portion (e.g., a portion of the upper surface) of each of the light-emitting elements LE or the second contact electrode CTE2. In the opened portion of the first insulating layer INS1, the common electrode CME may be electrically connected to the second contact electrode CTE2 (or the light-emitting element LE).

The first insulating layer INS1 may be used as a mask in an etching process for etching the epi-layer to form the light-emitting element LE, and may include a material suitable for use as a hard mask in the etching process of the light-emitting element LE. For example, the first insulating layer INS1 may include silicon oxide (SiOₓ) or other inorganic insulating material. In case that the first insulating layer INS1 is used as a hard mask to form the light-emitting element LE, the first insulating layer INS1 and the light-emitting element LE may have shapes and/or sizes that correspond to each other. For example, the first insulating layer INS1 and the light-emitting element LE may have shapes and/or sizes that correspond to each other when viewed from a top (e.g., in a plan view). In case that a process of removing the first insulating layer INS1 is performed after the etching process for forming the light-emitting element LE, the pixel PX may not include the first insulating layer INS1.

Each of the light-emitting elements LE may be surrounded by a protective film PSV. For example, the protective film PSV may surround the side surfaces of the light-emitting element LE. The protective film PSV may further surround the side surfaces of at least one of the reflective electrode RFE, the first contact electrode CTE1, the second contact electrode CTE2 and the first insulating layer INS1 of each pixel PX. The protective film PSV may include an opening (e.g., an opening exposing the opening OPN of the first insulating layer INS1) that exposes a portion (e.g., the upper surface) of the second contact electrode CTE2 (or the light-emitting element LE). At the opened portion of the protective film PSV, the common electrode CME may be electrically connected to the second contact electrode CTE2 (or the light-emitting element LE).

The protective film PSV may expose the side surfaces of the bonding electrode BDE. For example, the bonding electrode BDE may be individually formed in each pixel area by an etching process performed after the protective film PSV has been formed, and thus the side surfaces of the bonding electrode BDE may not be covered by the protective film PSV.

The protective film PSV may include at least one insulating material among silicon oxide (SiOₓ), silicon nitride (SiNₓ), aluminum oxide (AlₓO_{y}), titanium oxide (TiₓO_{y}) and hafnium oxide (HfOₓ), or other insulating material. The protective film PSV may protect the light-emitting element LE and improve the electrical stability of the light-emitting element LE.

Although not shown in FIG. 4, a reflective film may be further disposed on the side surfaces of each of the light-emitting elements LE. For example, the display panel DPN may further include a reflective film disposed on the protective film PSV to surround each of the light-emitting elements LE. The reflective film may include a metal having a high light reflectance or may be formed as a distributed Bragg reflector including multiple layers having different refractive indices.

The second insulating layer INS2 may be disposed around the light-emitting elements LE. For example, the second insulating layer INS2 may be disposed to fill the space between the light-emitting elements LE to surround the emission areas in which the light-emitting elements LE are disposed.

The second insulating layer INS2 may expose a portion of the light-emitting elements LE, e.g., the upper surface. The second insulating layer INS2 may be formed at a level higher than the light-emitting elements LE and may be opened above each of the light-emitting elements LE. For example, the second insulating layer INS2 may expose the opening OPN of the first insulating layer INS1 and may include an opening OPN having a size substantially equal to the size of the opening OPN of the first insulating layer INS1. As depicted in FIG. 3, a portion or region where the first insulating layer INS1 and the second insulating layer INS2 are commonly opened is indicated as an opening OPN. The opening OPN may refer to a portion where at least one insulating layer formed on the light-emitting element LE is opened so that the common electrode CME is electrically connected to the second contact electrode CTE2 or the light-emitting element LE, and may also be referred to as a contact portion or a contact hole. In another example, the second insulating layer INS2 may be formed at a level equal to or lower than the height of the light-emitting elements LE. The second insulating layer INS2 may be formed at a level similar to the height of the light-emitting elements LE. Accordingly, the level difference of the common electrode CME may be reduced, thereby prevent disconnection of the common electrode CME.

The second insulating layer INS2 may be made up of a single layer or multiple layers including at least one insulating material. For example, the second insulating layer INS2 may include silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or other inorganic insulating material.

The upper surface of the second insulating layer INS2 may be substantially flat. For example, the second insulating layer INS2 may be formed of a material and/or with a thickness suitable for having a substantially flat upper surface, or may be flattened by a planarization process (e.g., a chemical mechanical polishing (CMP) process) performed after the film has been formed.

The common electrode CME may be disposed on the light-emitting elements LE, the second contact electrodes CTE2, the first insulating layers INS1, and/or the second insulating layer INS2. For example, the common electrode CME may be disposed on the second insulating layer INS2 so that it overlaps the light-emitting elements LE, the second contact electrodes CTE2, and the first insulating layers INS1 in the third direction DR3. The common electrode CME may also be referred to as a second electrode.,

The common electrode CME may be disposed throughout the entire display area DA. For example, the common electrode CME may be a common layer that is commonly formed in and/or electrically connected to the light-emitting elements LE and the pixels PX including the same in the display area DA.

The common electrode CME may be electrically connected to the second contact electrodes CTE2. For example, the common electrode CME may be in contact with the second contact electrodes CTE2 (or the light-emitting elements LE) in the openings OPN of the first insulating layers INS1 and the second insulating layer INS2.

The common electrode CME may include a transparent conductive material that transmits light. For example, the common electrode CME may be made of indium tin oxide (ITO), indium zinc oxide (IZO), or other transparent conductive material. The common electrode CME may work as a cathode electrodes of the light-emitting elements LE or the pixels PX.

The second passivation layer CVL2 may be disposed on the common electrode CME. The second passivation layer CVL2 may be disposed throughout the entire display area DA to cover the common electrode CME. The second passivation layer CVL2 may also be disposed in a peripheral area (e.g., the peripheral area PHA of FIG. 1).

The upper surface of the second passivation layer CVL2 may be substantially flat. For example, the second passivation layer CVL2 may be formed of a material and/or with a thickness suitable to have a substantially flat upper surface, or may be flattened by a planarization process performed after the film has been formed.

The second passivation layer CVL2 may include at least one insulating material and may have a single-layer or multi-layer structure. The second passivation layer CVL2 may include, but is not limited to, an inorganic insulating material (e.g., silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or other inorganic insulating material).

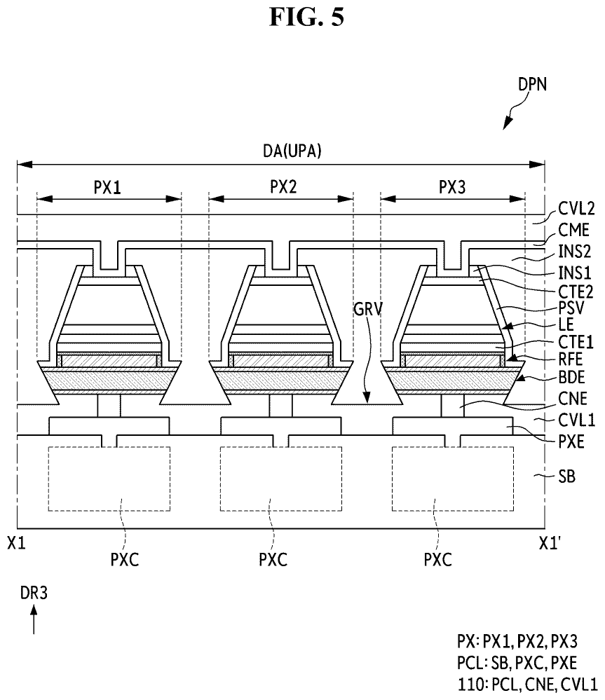

FIG. 5 is a schematic cross-sectional view showing a display panel according to an embodiment of the disclosure. FIG. 5 shows a different embodiment from the embodiment of FIG. 3 with respect to the bonding electrode BDE.

Referring to FIG. 5, the bonding electrode BDE may have a cross section in an inverted taper shape. For example, the width and/or area of the bonding electrode BDE may be gradually reduced toward the lower substrate 110 in the third direction DR3.

Since the bonding electrode BDE has an inverted taper shape, impurities (e.g., conductive byproducts such as gold (Au) residues that are not volatilized or removed) that may be generated during the etching process of the bonding electrode BDE may be suppressed or reduced from migrating to the upper side where the light-emitting element LE and the like are disposed. Accordingly, it is possible to prevent a short-circuit defect due to impurities that may be generated in the pixel formation process (also referred to as “pixel process”), and the electrical stability of the light-emitting element LE and the pixel PX including the light-emitting element LE may be ensured.

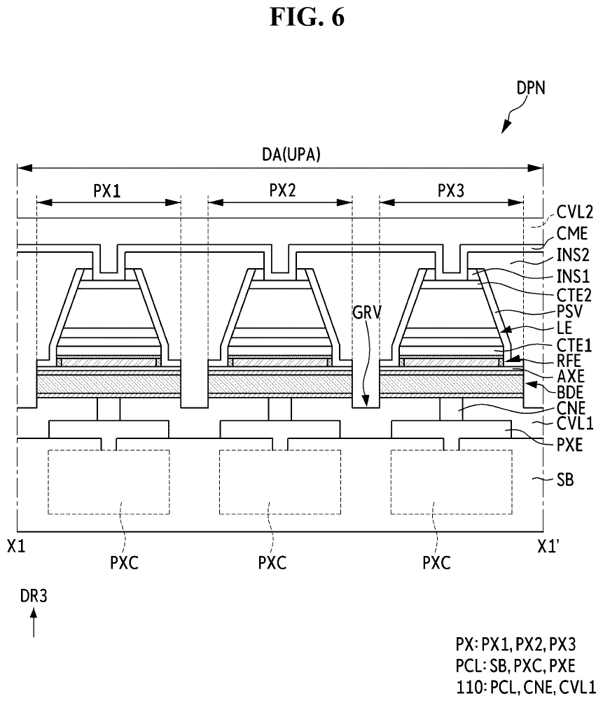

FIG. 6 is a schematic cross-sectional view showing a display panel according to an embodiment of the disclosure. FIG. 6 shows a display panel DPN further including an auxiliary layer AXE compared to FIG. 3.

Referring to FIG. 6, each of the pixels PX may further include an auxiliary layer AXE (also referred to as an auxiliary electrode layer) disposed between the bonding electrode BDE and the reflective electrode RFE. The auxiliary layer AXE may be formed of a material and/or thickness capable of ensuring bonding strength and conductivity, and may be made up of single-layer or multi-layer conductive layer(s). For example, the auxiliary layer AXE may include a transparent conductive material included in at least one of the first and second contact electrodes CTE1 and CTE2 (e.g., indium tin oxide (ITO), indium zinc oxide (IZO), or other transparent conductive material), a barrier material included in at least one of the first, second and third barrier layers BRL1, BRL2, and BRL3 (e.g., titanium (Ti) or other barrier metal), or other material.

By disposing the auxiliary layer AXE between the bonding electrode BDE and the reflective electrode RFE, the distance between the bonding electrode BDE and the light-emitting element LE may be increased. Accordingly, it is possible to prevent that conductive particles (e.g., gold (Au) residues) remaining in the pixel formation process including an etching process of the bonding electrode BDE move to the periphery of the light-emitting element LE and cause a short-circuit defect. Accordingly, the electrical stability of the light-emitting element LE and the pixel PX including the light-emitting element LE may be improved.

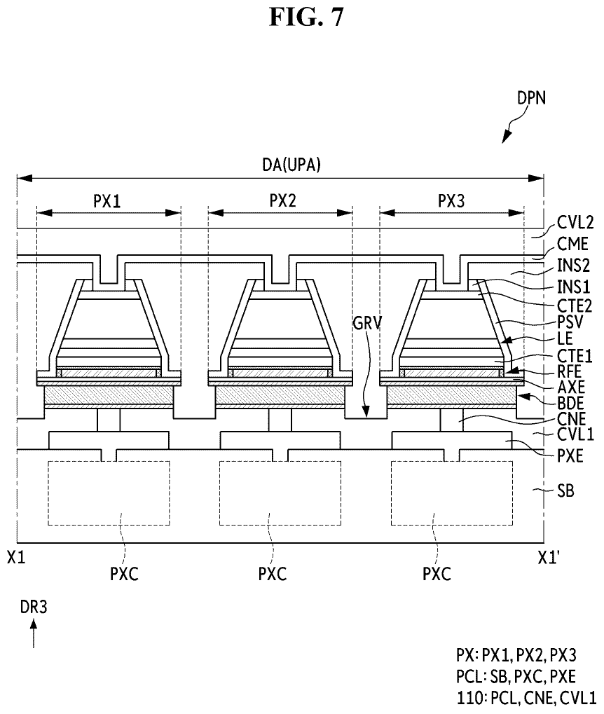

FIG. 7 is a schematic cross-sectional view showing a display panel according to an embodiment of the disclosure. FIG. 7 shows a different embodiment from the embodiment of FIG. 6 with respect to the bonding electrode BDE.

Referring to FIGS. 3 to 7, the second barrier layer BRL2 of the bonding electrode BDE and the auxiliary layer AXE on the second barrier layer BRL2 may protrude on the both sides of the bonding electrode BDE. For example, each of the second barrier layer BRL2 and the auxiliary layer AXE may have a size larger than the size of the bonding layer BMTL when viewed from a top (e.g., in a plan view), and the edges of each of the second barrier layer BRL2 and the auxiliary layer AXE may protrude outward from the bonding layer BMTL.

The auxiliary layer AXE and the bonding electrode BDE may be etched using the same mask. According to the embodiment of the disclosure, by utilizing the differences in the etch selectivities of the auxiliary layer AXE, the second barrier layer BRL2 and the bonding layer BMTL, the bonding layer BMTL may be overly etched so that the bonding layer BMTL has a smaller width than the auxiliary layer AXE and the second barrier layer BRL2.

Although the first barrier layer BRL1 has a width substantially equal to the width of the bonding layer BMTL according to the embodiment of FIG. 7, the embodiments of the disclosure are not limited thereto. For example, the first barrier layer BRL1 may also be etched to have a width greater than the width of the bonding layer BMTL, and accordingly, the first barrier layer BRL1 may protrude outward from the bonding layer BMTL.

According to the embodiment of FIG. 7 where each of the pixels PX includes the auxiliary layer AXE, each of the second barrier layer BRL2, and the auxiliary layer AXE protrudes outward from the bonding layer BMTL. It should be understood, however, that the embodiments of the disclosure are not limited thereto. For example, only one of the second barrier layer BRL2 and the auxiliary layer AXE may be etched to have a width greater than the width of the bonding layer BMTL and protrude outward from the bonding layer BMTL. In another example, as in the embodiments of FIGS. 3 to 5, the pixel PX may not include the auxiliary layer AXE, and the edges of the second barrier layer BRL2 may protrude outward from the bonding layer BMTL.

Since at least one of the second barrier layer BRL2 and the auxiliary layer AXE has a width greater than the width of the bonding layer BMTL and protrudes outward from the bonding layer BMTL, byproducts (e.g., gold (Au) residues) generated in the pixel formation process, including the etching process of the bonding electrode BDE, may be blocked from moving to the periphery of the light-emitting element LE. Therefore, it is possible to prevent more effectively short-circuit defects that may occur in light-emitting elements LE, etc.

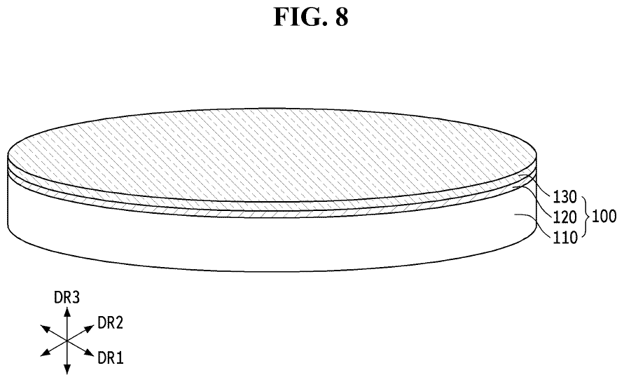

FIGS. 8 to 11 are schematic perspective views showing a method for fabricating a display device according to an embodiment. For example, FIGS. 8 to 11 show preparing a first substrate 100 and a second substrate 200 for fabricating a display panel DPN according to an embodiment, and disposing the second substrate 200 on the first substrate 100.

The first substrate 100 and the second substrate 200 of FIGS. 8 to 11 may include a plurality of cell areas for simultaneously fabricating a plurality of display panels DPN. It should be understood, however, that the embodiments of the disclosure are not limited thereto. For example, the first substrate 100 and the second substrate 200 may have a size equal to the size of a single display panel DPN.

Referring to FIG. 8, the first substrate 100 may be prepared. The first substrate 100 may include a lower substrate 110 of the display panel DPN, a first barrier material layer 120, and a first bonding material layer 130 (also referred to as a first bonding metal layer). The first barrier material layer 120 and the first bonding material layer 130 may be sequentially arranged or formed on the lower substrate 110 in the third direction DR3.

The lower substrate 110 may include a semiconductor circuit board PCL as shown in FIGS. 3 to 7. The lower substrate 110 may further include connection electrodes CNE and a first passivation layer CVL1 disposed on the semiconductor circuit board PCL. For example, as shown in FIGS. 3 to 7, the semiconductor circuit board PCL including a base substrate SB, pixel circuits PXC, and pixel electrodes PXE may be prepared, and then the first passivation layer CVL1 and the connection electrodes CNE may be formed on the semiconductor circuit board PCL, to prepare the lower substrate 110. The lower substrate 110 may include a cell area for forming at least one display panel DPN. For example, the lower substrate 110 of FIG. 8 may be prepared with a size and shape including a plurality of cell areas for simultaneously fabricating a plurality of display panels DPN. Each of the cell areas may include pixel circuits PXC, pixel electrodes PXE, connection electrodes CNE, and a first passivation layer CVL.

The first barrier material layer 120 and the first bonding material layer 130 are for forming bonding electrodes BDE of the pixels PX, and the lower layers of the bonding electrodes BDE may be formed from the first barrier material layer 120 and the first bonding material layer 130. For example, the first barrier layer BRL1 and the lower layer of the bonding layer BMTL of FIG. 4 may be formed from the first barrier material layer 120 and the first bonding material layer 130, respectively.

The first barrier material layer 120 may be formed using the above-listed materials as the material of the first barrier layer BRL1. The first barrier material layer 120 may be patterned into the first barrier layer BRL1 of each of the bonding electrodes BDE by an etching process performed after the bonding process.

The first bonding material layer 130 may be formed using the above-listed materials as the material of the bonding layer BMTL. For example, the first bonding material layer 130 may be formed of an alloy of gold (Au) and tin (SN), or other bonding metal. The first bonding material layer 130 may have a thickness suitable for a bonding process (e.g., wafer-to-wafer bonding by thermocompression). For example, the first bonding material layer 130 may have, but is not limited to, a thickness of about 100 nm to about 300 nm (e.g., about 200 nm). The first bonding material layer 130 may be patterned into the bonding layer BMTL (e.g., the lower portion of the bonding layer BMTL) of each of the bonding electrodes BDE by the bonding process and a subsequent etching process.

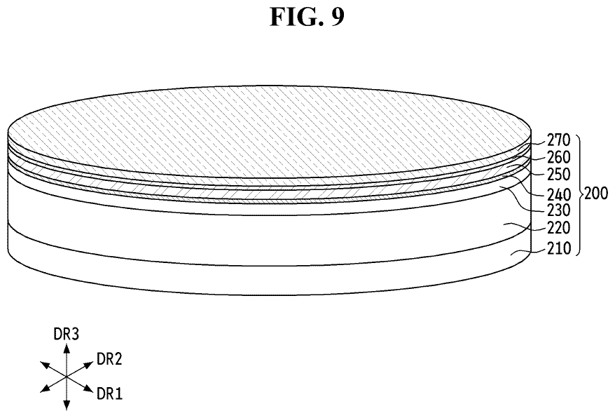

Referring to FIG. 9, a second substrate 200 for forming light-emitting elements LE of the display panel DPN may be prepared. The second substrate 200 may include a semiconductor substrate 210, an epi-layer 220, a first contact material layer 230, a third barrier material layer 240, a reflective material layer 250, a second barrier material layer 260, and a second bonding material layer 270 (also referred to as a second bonding metal layer). The epi-layer 220, the first contact material layer 230, the third barrier material layer 240, the reflective material layer 250, the second barrier material layer 260, and the second bonding material layer 270 may be sequentially disposed or formed on the semiconductor substrate 210 in the third direction DR3.

The semiconductor substrate 210 may be a fabrication substrate for fabricating light-emitting elements LE. For example, the semiconductor substrate 210 may be a growth substrate suitable for epitaxial growth.

The semiconductor substrate 210 may include a material such as GaAs, silicon (Si), sapphire, SiC, GaN, ZnO, etc. For example, the semiconductor substrate 210 may be a silicon or sapphire substrate. The type or material of the semiconductor substrate 210 is not particularly limited herein as long as epitaxial growth of the epi-layer 220 for fabricating the light-emitting elements LE is performed.

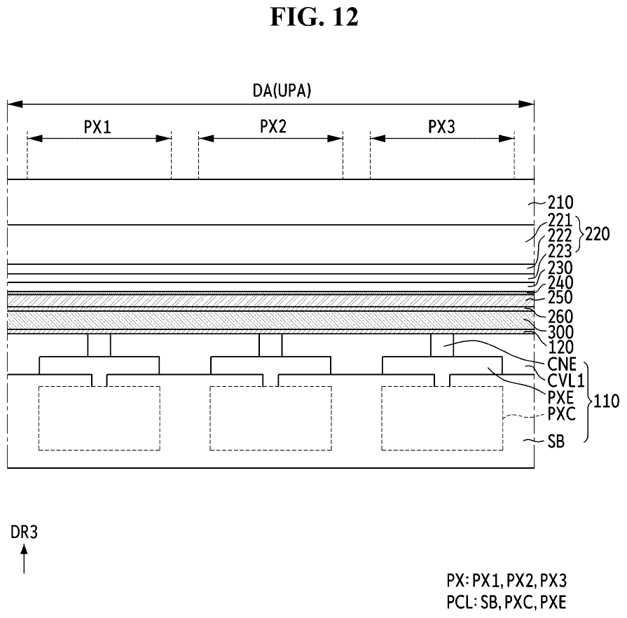

The epi-layer 220 may be for forming semiconductor layers of the light-emitting elements LE. For example, a first semiconductor layer SEM1, an emissive layer EML and a second semiconductor layer SEM2 of each of the light-emitting elements LE shown in FIGS. 3 to 7 may be formed from the epi-layer 220. For example, the epi-layer 220 may include a third epi-layer (the third epi-layer 221 of FIG. 12) for forming the second semiconductor layers SEM2 of the light-emitting elements LE, a second epi-layer (the second epi-layer 222 of FIG. 12) for forming the emissive layers EML of the light-emitting elements LE, and a first epi-layer (the first epi-layer 223 of FIG. 12) for forming the first semiconductor layers SEM1 of the light-emitting elements LE. For example, the epi-layer 220 may be formed on the semiconductor substrate 210 by epitaxial growth using the above-listed materials as the material for the second semiconductor layer SEM2, the emissive layer EML, and the first semiconductor layer SEM1 of the light-emitting element LE.

The first contact material layer 230, the third barrier material layer 240, the reflective material layer 250, the second barrier material layer 260, and the second bonding material layer 270 may form first contact electrodes CTE1, reflective electrodes RFE, and bonding electrodes BDE of the pixels PX. For example, the first contact electrodes CTE1 may be formed from the first contact material layer 230. The third barrier layer BRL3 and the reflective layer RMTL of each of the reflective electrodes RFE may be formed from the third barrier material layer 240 and the reflective material layer 250, respectively. The upper layers of the bonding electrodes BDE, for example, the second barrier layer BRL2 and the upper portions of the bonding layer BMTL of FIG. 4 may be formed from the second barrier material layer 260 and the second bonding material layer 270, respectively.

The first contact material layer 230 may be formed using the above-listed materials (e.g., ITO, etc.) as the material of the first contact electrodes CTE1. The first contact material layer 230 may have a thickness suitable for working as a contact electrode for stably connecting the light-emitting elements LE with the respective bonding electrodes BDE. For example, the first contact material layer 230 may have, but is not limited to, a thickness of about 100 nm. The first contact material layer 230 may be patterned into the first contact electrode CTE1 of each of the pixels PX by an etching process performed after the bonding process.

The third barrier material layer 240 may be formed using the above-listed material (e.g., TiN, etc.) as the material of the third barrier layer BRL3. The third barrier material layer 240 may be a thin film having a limited thickness, e.g., a thickness of about 20 nm or less. It should be understood, however, that the embodiments of the disclosure are not limited thereto. The third barrier material layer 240 may be patterned into the third barrier layer BRL3 of each of the reflective electrodes RFE by an etching process performed after the bonding process.

The reflective material layer 250 may be formed using the above-listed materials (e.g., Al, etc.) as the material of the reflective layer RMTL. The reflective material layer 250 may have a thickness that reflects light output from the light-emitting elements LE (e.g., a thickness allowing for a reflectance in a target range). For example, the reflective material layer 250 may have, but is not limited to, a thickness of about 100 nm to about 200 nm. The reflective material layer 250 may be patterned into the reflective layer RMTL of each of the reflective electrodes RFE by an etching process performed after the bonding process.

The second barrier material layer 260 may be formed using the above-listed material (e.g., Ti, etc.) as the material of the second barrier layer BRL2. The second barrier material layer 260 may be patterned into the second barrier layer BRL2 of each of the bonding electrodes BDE by an etching process performed after the bonding process.

The second bonding material layer 270 may be formed using the above-listed materials as the material of the bonding layer BMTL. For example, the second bonding material layer 270 may be formed of an alloy of gold (Au) and tin (SN), or other bonding metal. The second bonding material layer 270 may have a thickness suitable for the bonding process. For example, the second bonding material layer 270 may have, but is not limited to, a thickness of about 100 nm to about 300 nm (e.g., about 200 nm). The second bonding material layer 270 may be patterned into the bonding layer BMTL (e.g., the upper portion of the bonding layer BMTL) by an etching process performed after the bonding process.

According to an embodiment of the disclosure, in case that the display panel DPN further including an auxiliary layer AXE disposed on each bonding electrode BDE is fabricated as in the embodiment of FIG. 6 or FIG. 7, a conductive layer for forming the auxiliary layer AXE may be formed on the reflective material layer 250 prior to forming the second barrier material layer 260, and the second barrier material layer 260 may be formed on the conductive layer. The conductive layer may be formed using the above-listed conductive materials as the material of the auxiliary layer AXE.

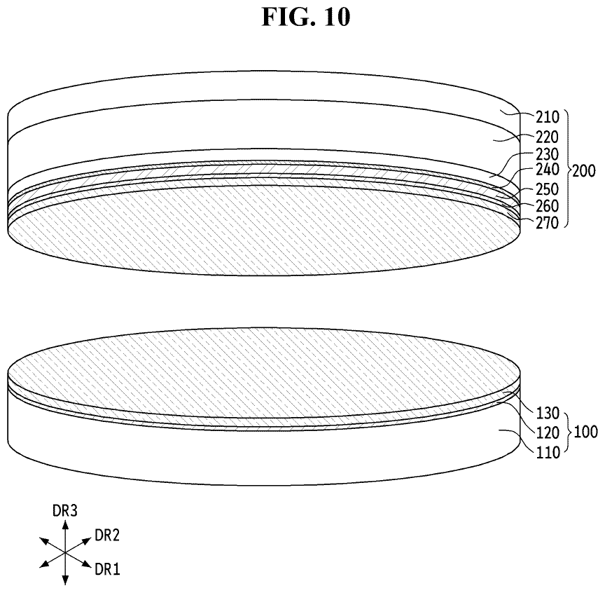

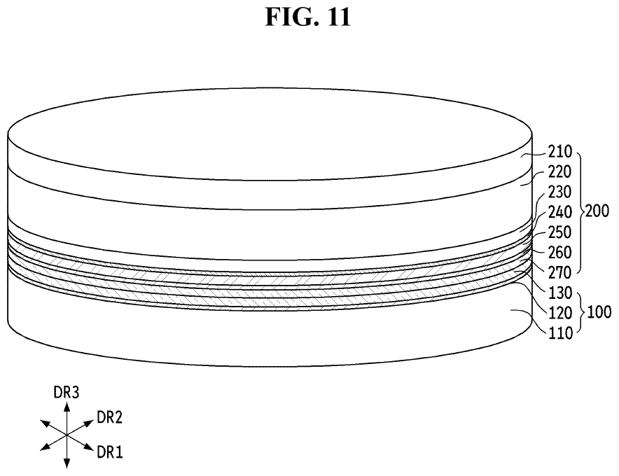

Referring to FIGS. 10 and 11, the first substrate 100 and the second substrate 200 may be disposed such that they face each other in the third direction DR3. For example, after aligning the first substrate 100 with the second substrate 200 such that the first bonding material layer 130 of the first substrate 100 and the second bonding material layer 270 of the second substrate 200 face each other, the first bonding material layer 130 and the second bonding material layer 270 may be brought into contact or close contact with each other.

Subsequently, the first bonding material layer 130 and the second bonding material layer 270 may be melted to bond (or attach) the first substrate 100 with the second substrate 200. For example, the second substrate 200 may be disposed on the first substrate 100 and then heat and pressure may be applied to bond the first substrate 100 with the second substrate 200.

FIGS. 12 to 24 are schematic cross-sectional views showing a method of fabricating a display device according to an embodiment. For example, FIGS. 12 to 24 show pixel formation processes performed after the bonding the first substrate 100 with the second substrate 200. The pixel formation process may include a process of forming pixels PX including light-emitting elements LE in each cell area on the lower substrate 110. FIGS. 12 to 24 show only a portion of one cell area, for example, show a unit pixel area UPA located in one cell area. A unit pixel area UPA of FIGS. 12 to 24 may correspond to the unit pixel area UPA of FIG. 3. The display panel DPN according to the embodiments of FIGS. 5 to 7 may be fabricated in a similar manner with the display panel DPN according to the embodiment of FIG. 3.

Referring to FIGS. 11 and 12, the second substrate 200 may be bonded to the first substrate 100 by bonding the first bonding material layer 130 to the second bonding material layer 270 to form a bonding layer 300. For example, a bonding process may be performed by applying heat and pressure while the second substrate 200 is disposed on the first substrate 100 so that the first bonding material layer 130 and the second bonding material layer 270 are in contact with each other. Accordingly, the first bonding material layer 130 and the second bonding material layer 270 may be melted to form a single bonding layer 300. The bonding layer 300 may be patterned into a bonding layer BMTL of each of the bonding electrodes BDE by an etching process performed after the bonding process.

FIG. 12 shows the structure of the epi-layer 220 in more detail. For example, the epi-layer 220 may include a first epi-layer 223 (e.g., a p-type semiconductor layer) for forming first semiconductor layers SEM1 of the light-emitting elements LE, a second epi-layer 222 (e.g., a multi-quantum well layer including a quantum well layer and a barrier layer) for forming emissive layers EML of the light-emitting elements LE, and a third epi-layer 221 (e.g., an n-type semiconductor layer) for forming second semiconductor layers SEM2 of the light-emitting elements LE.

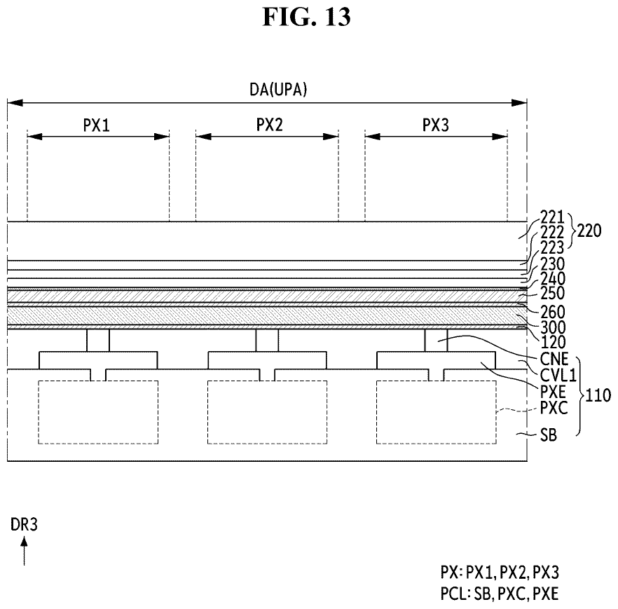

Referring to FIGS. 12 and 13, after the bonding layer 300 has been formed, the semiconductor substrate 210 may be separated from the epi-layer 220. As a result, the semiconductor substrate 210 may be removed on the epi-layer 220.

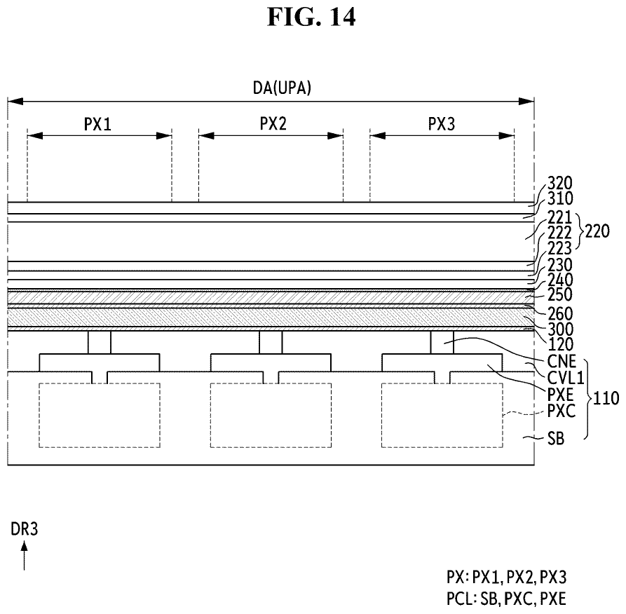

Referring to FIG. 14, a second contact material layer 310 and a first insulating material layer 320 may be sequentially formed (for example, deposited) on the epi-layer 220. The second contact material layer 310 and the first insulating material layer 320 are for forming the second contact electrodes CTE2 and the first insulating layers INS1 of the pixels PX, and the second contact electrode CTE2 and the first insulating layer INS1 of each of the pixels PX may be formed from the second contact material layer 310 and the first insulating material layer 320.

The second contact material layer 310 may be formed using the above-listed materials (e.g., ITO, etc.) as the material of the second contact electrodes CTE2. The second contact material layer 310 may have a thickness suitable for working as a contact electrode for smoothly connecting the light-emitting elements LE with the common electrode CME. The second contact material layer 310 may be formed to allow light emitted from the light-emitting elements LE to transmit it. For example, the second contact material layer 310 may include a transparent conductive material and may have a thickness of about 100 nm. It should be understood, however, that the embodiments of the disclosure are not limited thereto. According to the embodiment of the disclosure, if the display panel DPN that does not include second contact electrodes CTE2 (e.g., the display panel DPN in which the common electrode CME is disposed directly on light-emitting elements LE) is fabricated, the process of forming the second contact material layer 310 may be omitted.

The first insulating material layer 320 may be formed using the above-listed materials as the material of the first insulating layers INS1. The first insulating material layer 320 may be formed using, but is not limited to, a material suitable for use as a hard mask in an etching process for etching the epi-layer 220 to form light-emitting elements LE, such as SiO₂.

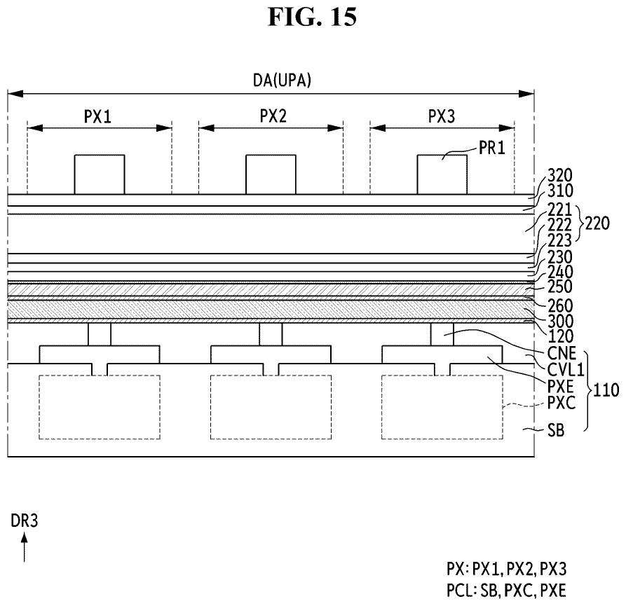

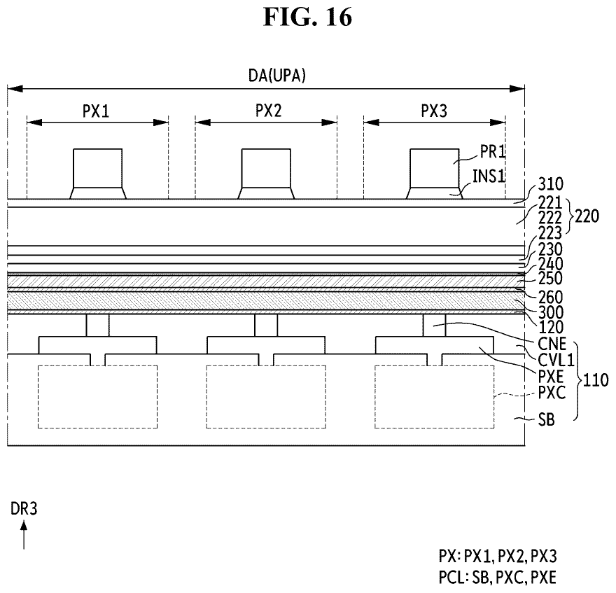

Referring to FIGS. 15 and 16, the first insulating material layer 320 may be etched to form the first insulating layer INS1 for each of the pixels PX. For example, a first mask PR1 may be placed on a portion of the first insulating material layer 320, and then the first insulating material layer 320 may be etched using the first mask PR1, thereby forming the first insulating layer INS1 for each of the pixels PX. The first mask PR1 may be, but is not limited to, a mask pattern including a photoresist material. The first mask PR1 may be formed in a shape and/or size corresponding to those of the first insulating layer INS1 (or the light-emitting element LE) to be formed. The first mask PR1 may be removed after the first insulating layer INS1 has been formed.

The first insulating layer INS1 may be used as a mask for etching the epi-layer 220 to form the light-emitting element LE of each of the pixels PX. Accordingly, the first insulating layer INS1 may be formed to have a shape (e.g., a planar shape) and a size (e.g., a planar area) corresponding to the shape and the size of each of the light-emitting elements LE at locations where the light-emitting elements LE are to be formed.

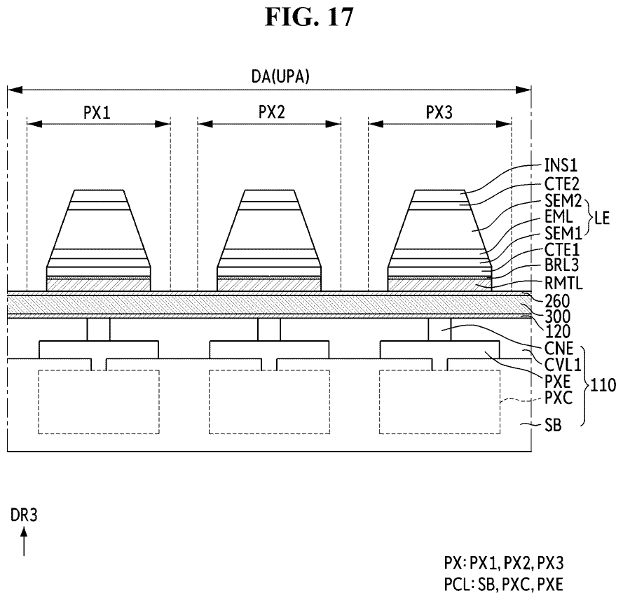

Referring to FIGS. 16 and 17, the second contact material layer 310 and the epi-layer 220 may be etched to form the second contact electrode CTE2 and the light-emitting element LE of each of the pixels PX. In the mask process for etching the epi-layer 220, the first contact material layer 230, the third barrier material layer 240 and the reflective material layer 250 may be etched to form the first contact electrode CTE1, the third barrier layer BRL3, and the reflective layer RMTL of each of the pixels PX.

The second contact material layer 310, the epi-layer 220, the first contact material layer 230, the third barrier material layer 240, and the reflective material layer 250 may be etched simultaneously and/or sequentially by an etching process using the first insulating layer INS1 as a mask (e.g., a hard mask). For example, the second contact electrode CTE2, the light-emitting element LE, the first contact electrode CTE1, the third barrier layer BRL3, and the reflective layer RMTL of each of the pixels PX may be formed. In case that the second contact material layer 310, the epi-layer 220, the first contact material layer 230, the third barrier material layer 240, and the reflective material layer 250 are etched using the first insulating layer INS1 as a mask, the second contact material layer 310, the epi-layer 220, the first contact material layer 230, the third barrier material layer 240, and the reflective material layer 250 may be etched in a shape (e.g., a planar shape) and size (e.g., a planar area) corresponding to those of the first insulating layer INS1.

The type or ratio of the etching gas may vary depending on the material of different layers being etched. For example, the type or ratio of the etching gas may be adjusted or changed so that each layer to be etched is etched.

Although the etching process was conducted up to the reflection layer RMTL in the etching process using the first insulating layer INS1 as a hard mask as depicted in FIG. 17, the embodiments of the disclosure are not limited thereto. For example, the reflective material layer 250 may be etched for a sufficient amount of time for the process margin required for stable etching of the reflective material layer 250. Accordingly, a part of the second contact material layer 310 (e.g., the upper portion) may be etched along with the reflective material layer 250.

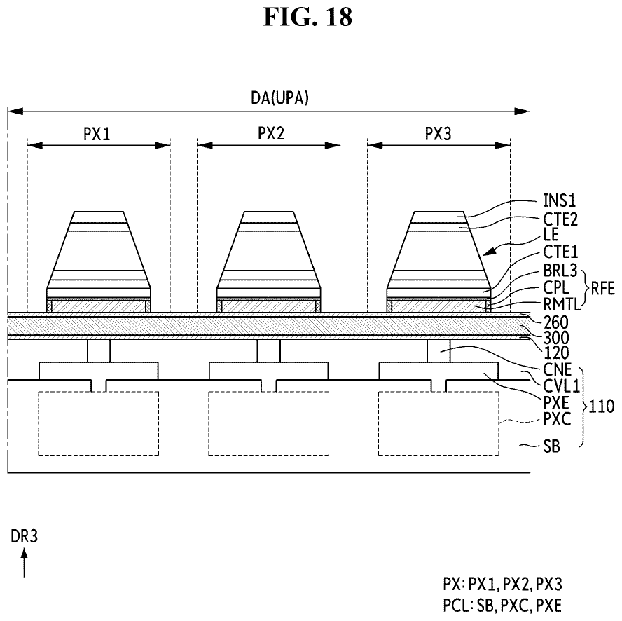

Referring to FIG. 18, a capping film CPL covering the side surfaces of the reflective layer RMTL may be formed. The forming the capping film CPL may include forming an oxide film on the side surfaces of the reflective layer RMTL exposed by etching the reflective material layer 250. For example, the capping film CPL may be formed as an oxide film or may include an oxide film.

According to the embodiment of the disclosure, immediately after etching the reflective layer RMTL by the etching process using the first insulating layer INS1 as the hard mask, the capping film CPL may be formed on the side surfaces of the reflective layer RMTL through continuous post-processing. For example, by performing continuous post-processing using high-temperature (e.g., gaseous) H₂O and CH₄/O₂ in a chamber where vacuum is maintained, the side surfaces of the reflective layer RMTL may be oxidized to form the capping film CPL. The reflective layer RMTL may include aluminum (Al), and the capping film CPL formed by post-processing may include aluminum oxide (AlₓO_{y}).

It is to be understood that the material and/or method for forming the capping film CPL are not limited by the above-described embodiment. For example, after forming the reflective layer RMTL, a separate deposition process and/or etching process, etc., for forming the capping film CPL may be performed to form the capping film CPL on the side surfaces of the reflective layer RMTL. The capping film CPL may be formed of other material than aluminum oxide (AlₓO_{y}). The capping film CPL may be formed of a material and/or with a thickness that protects the reflective layer RMTL in a subsequent process for forming the bonding electrode BDE, etc. For example, the capping film CPL may be formed of a material and/or with a thickness that is suitable for preventing the material (e.g., aluminum (Al)) of the reflective layer RMTL from being eluted.

The capping film CPL may be formed to cover (e.g., completely cover) the exposed surfaces, e.g., the side surfaces of the reflective layer RMTL. Accordingly, it is possible to reliably protect the reflective layer RMTL during the subsequent process.

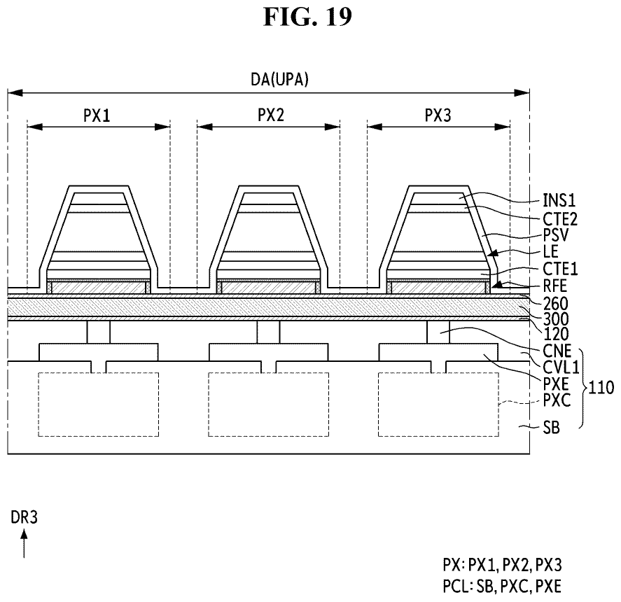

Referring to FIG. 19, a protective film PSV may be formed to cover the side surfaces of the light-emitting elements LE. The protective film PSV may be formed using the above-listed materials for the protective film PSV (e.g., AlₓO_{y} (for example, Al₂O₃) or other insulating material). The protective film PSV may be first formed throughout the entire display area DA and etched in a subsequent process. For example, the protective film PSV may cover (e.g., entirely cover) the first barrier material layer 120, the bonding layer 300, the second barrier material layer 260, the reflective electrodes RFE, the first contact electrodes CTE1, the light-emitting elements LE, the second contact electrodes CTE2, and the first insulating layers INS1.

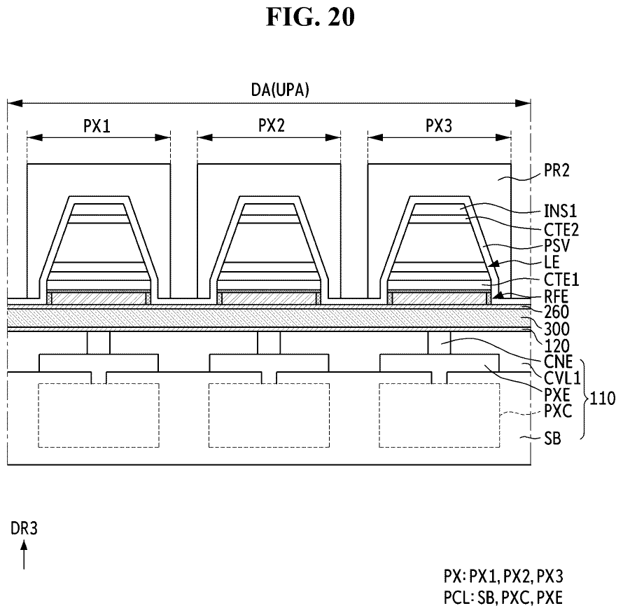

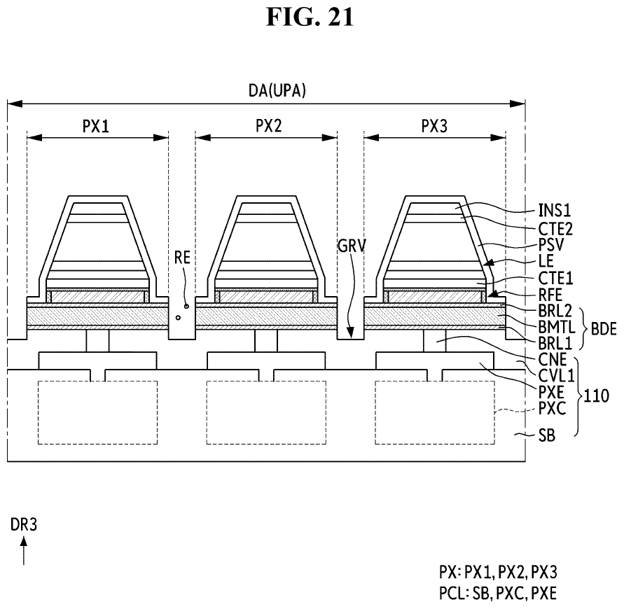

Referring to FIGS. 20 and 21, the protective film PSV, the second barrier material layer 260, the bonding layer 300, and the first barrier material layer 120 may be etched to form the protective film PSV and the bonding electrode BDE for each of the pixels PX. For example, a second mask PR2 covering the light-emitting elements LE may be disposed on the protective film PSV, and the exposed portions of the protective film PSV, the second barrier material layer 260, the bonding layer 300, and the first barrier material layer 120 may be etched. The second mask PR2 may be, but is not limited to, a mask pattern including a photoresist material.

The protective film PSV, the second barrier material layer 260, the bonding layer 300, and the first barrier material layer 120 may be etched simultaneously and/or sequentially in the etching process utilizing the second mask PR2. For example, the protective film PSV and the bonding electrode BDE may be formed in each of the pixels PX. The bonding electrode BDE may include a first barrier layer BRL1, a bonding layer BMTL, and a second barrier layer BRL2 formed from the first barrier material layer 120, the bonding layer 300, and the second barrier material layer 260, respectively.

The second mask PR2 may be formed in a shape (e.g., a circular shape, a rectangular shape, a polygonal shape other than a rectangular shape, or other shapes when viewed from a top (e.g., in a plan view)) and/or a size corresponding to those of the bonding electrode BDE to be formed. The second mask PR2 may cover (e.g., completely cover) the light-emitting element LE and the reflective electrode RFE of each of the pixels PX. For example, the second mask PR2 may be disposed in each pixel area to cover the light-emitting element LE and the periphery of the light-emitting element LE. Accordingly, when viewed from a top (e.g., in a plan view), the protective film PSV and the bonding electrode BDE may have a larger size than the light-emitting element LE and the reflective electrode RFE. The second mask PR2 may be removed after the bonding electrode BDE has been formed.

The type or ratio of the etching gas may vary depending on the material of each layer to be etched during the etching process using the second mask PR2. For example, the type or ratio of the etching gas may be adjusted or changed so that each layer to be etched is etched.

The bonding layer 300 and the like may be etched using Cl₂ gas. Since the reflective layer RMTL of the reflective electrode RFE is etched in a previous mask process and covered with the capping film CPL, it is possible to prevent the material of the reflective layer RMTL from being eluted while the etching process of the bonding layer 300 and the like is performed.

The bonding electrodes BDE may be etched after the protective film PSV has been formed. For example, after the protective film PSV has been formed, the protective film PSV and the bonding electrodes BDE may be etched by an etching process using the second mask PR2. Accordingly, the side surfaces of the bonding electrodes BDE may not be covered by the protective film PSV. For example, the protective film PSV may cover the side surfaces of each light-emitting element LE and the reflective electrode RFE, but may expose the side surfaces of each bonding electrode BDE.

Since the mask process for forming the reflective electrode RFE is separated from the mask process for forming the bonding electrode BDE, the time taken for performing the etching process using the second mask PR2 may be reduced. Accordingly, by-products resulting from the etching of the bonding layer 300, such as gold (Au) residues RE, may be significantly reduced. Since the consumption of the second mask PR2 is reduced, each of the light-emitting element LE may be covered, thereby blocking by-products from sticking to the periphery of the light-emitting element LE.

There may be level differences between the reflective electrode RFE and the bonding electrode BDE since the reflective electrode RFE and the bonding electrode BDE are etched into different sizes. The distance between the exposed side surfaces of the bonding electrode BDE and the light-emitting element LE may increase due to the level differences. As a result, a short-circuit defect of the light-emitting element LE caused by by-products generated during the process of forming the bonding electrode BDE may be prevented or reduced.

According to the embodiments described above, it is possible to prevent, reduce, or suppress a short-circuit defect that may occur in a pixel PX due to impurities. For example, it is possible to prevent, reduce or suppress that conductive by-products which may be generated as aluminum (Al) of the reflective layer RMTL is dissolved, or conductive by-products such as gold (Au) residues RE generated during the process of forming the bonding electrode BDE stick to the periphery of the light-emitting element LE to cause a short-circuit defect.

According to the embodiment of the disclosure, an etching process for forming bonding electrodes BDE may be performed with a sufficient process margin so that the bonding electrodes BDE of the pixels PX are separated. Accordingly, the first passivation layer CVL1 may be etched to a certain thickness between the pixels PX to form grooves GRV.

According to an embodiment of the disclosure, in order to fabricate the display panel DPN including the bonding electrodes BDE of an inverted taper shape as in the embodiment of FIG. 5, the bonding electrodes BDE may be etched into the inverted taper shape in an etching process using the second mask PR2. For example, etching conditions or environments may be controlled or changed so that each of the bonding electrodes BDE is formed in the inverted taper shape.

According to an embodiment of the disclosure, in order to fabricate the display panel DPN further including an auxiliary layer AXE disposed on each bonding electrode BDE as in the embodiment of FIG. 6 or FIG. 7, a conductive layer for forming the auxiliary layer AXE may be formed on the reflective material layer 250 prior to forming the second barrier material layer 260, and the conductive layer may be etched in the etching process using the second mask PR2. Accordingly, the auxiliary layer AXE corresponding to the shape and/or size of the bonding electrode BDE may be formed on the bonding electrode BDE. It should be understood, however, that the embodiments of the disclosure are not limited thereto. For example, a conductive layer for forming the auxiliary layer AXE may be formed together with the reflective layer RMTL in the etching process using the first insulating layer INS1 as the hard mask. For example, the auxiliary layer AXE may be formed in a shape corresponding to the shape and/or size of the reflective layer RMTL.

According to an embodiment of the disclosure, in order to form the second barrier layer BRL2 that protrudes outward from the bonding layer BMTL when viewed from a top (e.g., in a plan view) as in the embodiment of FIG. 7, the materials of the second barrier layer BRL2 and the bonding layer BMTL, and/or etching conditions or environments, etc., may be adjusted to form the second barrier layer BRL2 and the bonding layer BMTL having different widths and/or areas. For example, by utilizing the difference in the etch selectivity between the second barrier layer BRL2 and the bonding layer BMTL, the bonding layer BMTL may be overly etched compared to the second barrier layer BRL2. In order to fabricate the display panel DPN further including the auxiliary layer AXE, in case that the auxiliary layer AXE is formed with a larger width and/or area than the bonding layer BMTL like the second barrier layer BRL2, by utilizing the difference in the etch selectivity between the auxiliary layer AXE and the bonding layer BMTL in the same manner, the bonding layer BMTL may be overly etched compared to the auxiliary layer AXE.

According to an embodiment of the disclosure, in order to form the first barrier layer BRL1 with a larger width and/or area than the auxiliary layer AXE, the difference in etch selectivity between the first barrier layer BRL1 and the bonding layer BMTL may be utilized in the same manner. Accordingly, the first barrier layer BRL1 may protrude outward from the bonding layer BMTL.

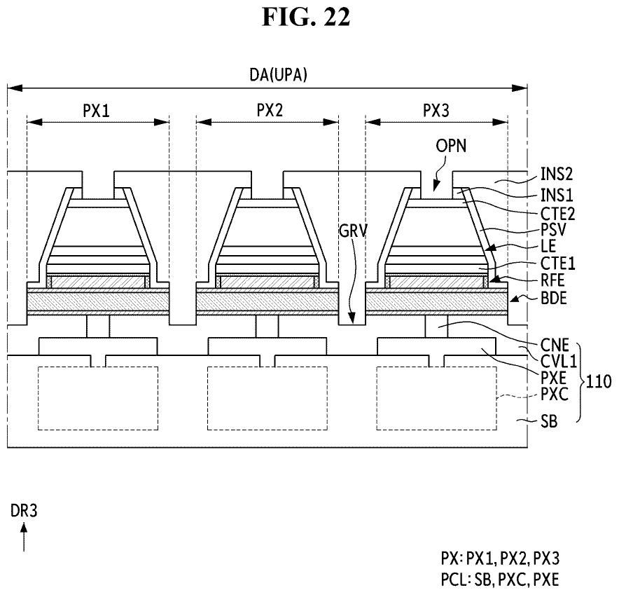

Referring to FIG. 22, a second insulating layer INS2 may be formed on the protective film PSV of each of the pixels PX. The second insulating layer INS2 may first be formed throughout the entire display area DA. For example, the second insulating layer INS2 may cover the bonding electrodes BDE, the reflective electrodes RFE, the light-emitting elements LE, the first insulating layers INS1, and the passivation films PSV of the pixels PX, and the space between the light-emitting elements LE may be filled with the second insulating layer INS2. The second insulating layer INS2 may be formed using the above-listed materials, or other insulating material.

The second insulating layer INS2 may be formed using an inorganic insulating material such as SiOₓ (e.g., SiO₂), and then the upper surface of the second insulating layer INS2 may be flattened by a planarization process (e.g., a CMP process, etc.). In another example, the second insulating layer INS2 may be formed to a sufficient thickness so that the upper surface of the second insulating layer INS2 is substantially flat. It should be understood, however, that the embodiments of the disclosure are not limited thereto. For example, the second insulating layer INS2 may include at least one organic insulating layer including an organic insulating material, and the second insulating layer INS2 may be formed to be substantially flat.

Subsequently, the first insulating layer INS1, the protective film PSV and the second insulating layer INS2 may be etched above each of the light-emitting elements LE to form an opening OPN exposing a portion of each of the second contact electrodes CTE2 (or the light-emitting elements LE). The protective film PSV may include a different material (e.g., a material having a different etch selectivity) than the first insulating layer INS1 and/or the second insulating layer INS2, and may be etched over a larger area than the first insulating layer INS1 and/or the second insulating layer INS2. For example, the protective film PSV may be removed (e.g., completely removed) from the upper surface of the first insulating layer INS1 to cover (e.g., only cover) the side surfaces of the first insulating layer INS1, but the embodiments of the disclosure are not limited thereto.

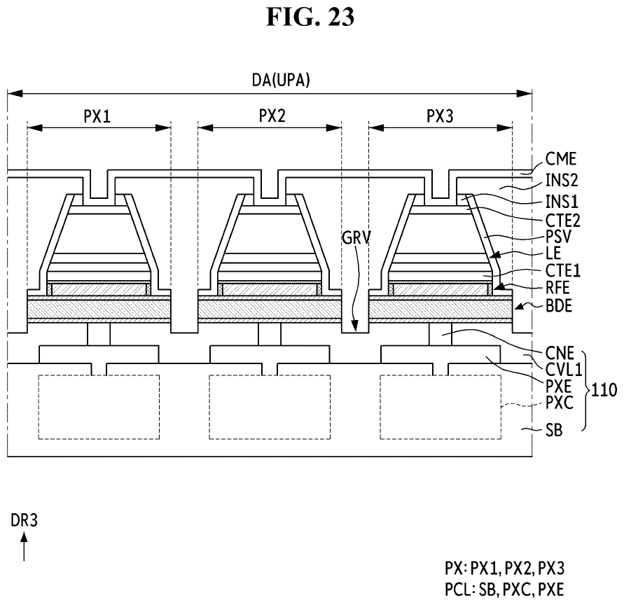

Referring to FIG. 23, a common electrode CME may be formed on the second insulating layer INS2. The common electrode CME may be formed throughout the light-emitting elements LE using the above-listed materials. For example, the common electrode CME may be formed throughout the entire surface of the display area DA. The common electrode CME may be formed also in the opening OPN of FIG. 22. Accordingly, the common electrode CME and the second contact electrodes CTE2 (or the light-emitting elements LE) may be electrically connected with each other. For example, the common electrode CME may be electrically connected to the light-emitting element LE by being in contact with the second contact electrodes CTE2 (or the light-emitting elements LE) in the openings OPN.

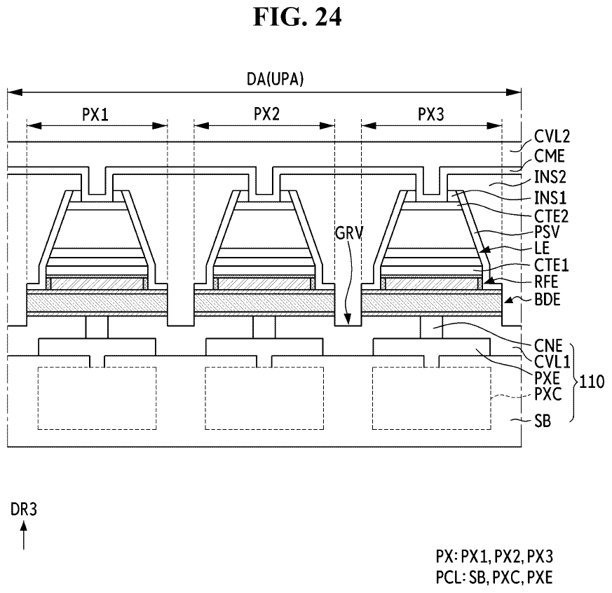

Referring to FIG. 24, a second passivation layer CVL2 may be formed on the common electrode CME. The second passivation layer CVL2 may be formed using a material suitable for protecting the light-emitting elements LE and the pixels PX. For example, the second passivation layer CVL2 may be formed throughout the entire common electrode CME using the above-listed inorganic insulating materials or organic insulating materials. For example, the display panel DPN according to the embodiment of FIG. 3 may be fabricated.

According to an embodiment of the disclosure, in case that the display panel DPN or the display device 10 includes an additional element disposed on the second passivation layer CVL2, a process for forming or disposing the additional element may be performed after the formation of the second passivation layer CVL2. For example, in order to fabricate the display device 10 including an optical structure disposed on the second passivation layer CVL2, e.g., a micro lens overlapping each light-emitting element LE, a process of forming or disposing the micro lens on the second passivation layer CVL2 may be performed. The micro lens may be formed integrally with the display panel DPN or may be formed separately from the display panel DPN and disposed on the display panel DPN.

As described above, the display device 10 according to the embodiments may include the reflective electrode RFE including the reflective layer RMTL and the capping film CPL covering the side surface of the reflective layer RMTL. According to the embodiments, the capping film CPL may be formed before etching the bonding layer BMTL disposed under the reflective layer RMTL.

In the display device 10 and the method for fabricating the same according to the embodiments, it is possible to prevent, reduce, or suppress short-circuit defects that may occur in a pixel formation process for forming pixels PX, etc. Accordingly, the electrical stability of the pixels PX and the display device 10 including the pixels PX may be increased, and the yield of the display device 10 may be improved.

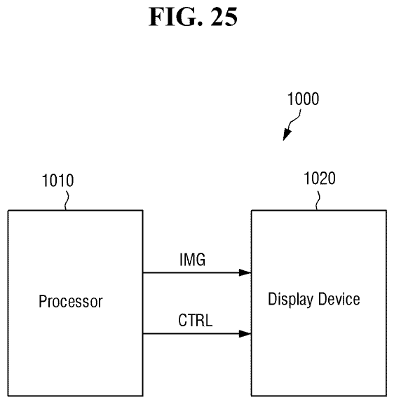

FIG. 25 is a schematic block diagram illustrating a display system according to an embodiment of the disclosure.

Referring to FIG. 25, a display system 1000 may include a processor 1010 and a display device 1020.

The processor 1010 may perform various tasks and various calculations. The processor 1010 may include an Application Processor (AP), a Graphics Processing Unit (GPU), a microprocessor, a Central Processing Unit (CPU), and the like. The processor 1010 may be electrically connected to other components of the display system 1000 through a bus system to control the components of the display system 1000.

The processor 1010 may transmit image data IMG and a control signal CTRL to the display device 1020. The display device 1020 may display an image (or images) based on the input image data IMG and the control signal CTRL. The display device 1020 may be configured identical to the display device 10 described with reference to FIG. 1. The input image data IMG and the control signal CTRL may be provided as the input image data IMG and the control signal CTRL, which are shown in FIG. 1, respectively.

The display system 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

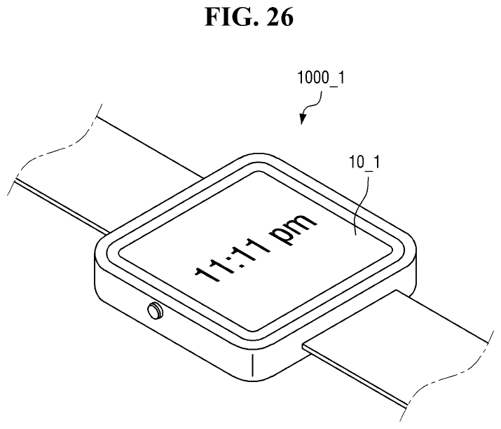

FIG. 26 is a schematic view showing an example of a smart watch including a display device according to an embodiment of the disclosure.

Referring to FIG. 26, a display device 10_1 according to an embodiment may be applied to a smart watch 1000_1 that is one of smart devices.

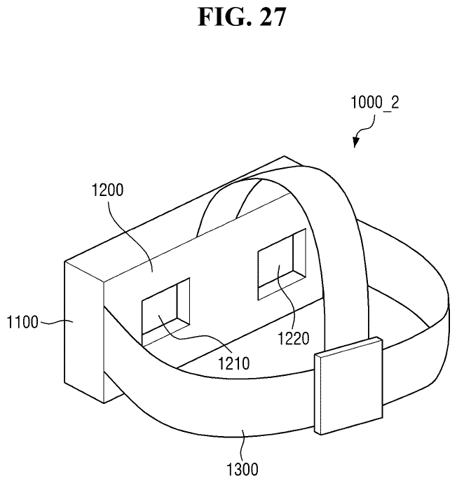

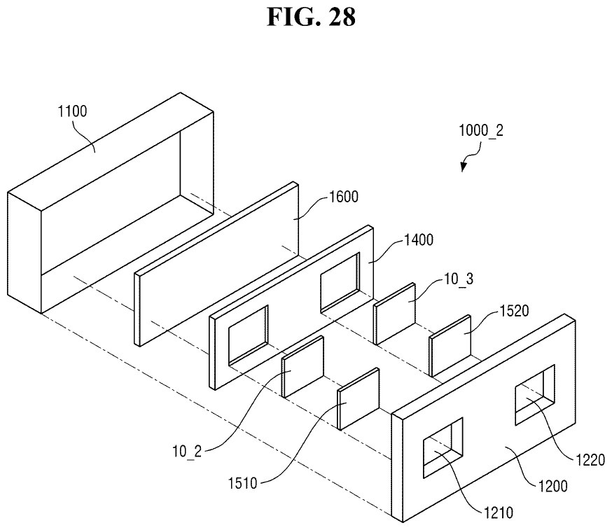

FIGS. 27 and 28 are schematic views showing an example of a head-mounted display device including a display device according to an embodiment.

Referring to FIGS. 27 and 28, a head-mounted display device 1000_2 according to an embodiment may be a virtual reality device. The head-mounted display device 1000_2 includes a first display device 10_2, a second display device 10_3, a display device housing 1100, a housing cover 1200, a first eyepiece 1210, a second eyepiece 1220, a head strap band 1300, a middle frame 1400, a first optical member 1510, a second optical member 1520, and a control circuit board 1600.

The first display device 10_2 provides images to a user's left eye, and the second display device 10_3 provides images to the user's right eye.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600, and may be disposed between the second display device 10_3 and the control circuit board 1600. The middle frame 1400 may support the first display device 10_2, the second display device 10_3, and may be fixed to the control circuit board 1600.

The control circuit board 1600 may be disposed between the middle frame 1400 and the display device housing 1100. The control circuit board 1600 may be electrically connected to the first display device 10_2 and the second display device 10_3 through a connector. The control circuit board 1600 may convert an image source input from the outside into video data and may transmit the video data to the first display device 10_2 and the second display device 10_3 through the connector.

The control circuit board 1600 may transmit video data associated with a left-eye image optimized for the user's left eye to the first display device 10_2, and may transmit video data associated with a right-eye image optimized for the user's right eye to the second display device 10_3. In another example, the control circuit board 1600 may transmit the same digital video data to the first display device 10_2 and the second display device 10_3.

The display device housing 1100 may accommodate the first display device 10_2, the second display device 10_3, the middle frame 1400, the first optical member 1510, the second optical member 1520, and the control circuit board 1600. The housing cover 1200 may be disposed to cover the open face of the display device housing 1100. The housing cover 1200 may include the first eyepiece 1210 where the user's left eye is placed, and the second eyepiece 1220 where the user's right eye is placed. Although the first eyepiece 1210 and the second eyepiece 1220 are separately disposed as depicted in FIGS. 1 and 27, the embodiments of the disclosure are not limited thereto. The first eyepiece 1210 and the second eyepiece 1220 may be combined into a single element.

The first eyepiece 1210 may be aligned with the first display device 10_2 and the first optical member 1510, and the second eyepiece 1220 may be aligned with the second display device 10_3 and the second optical member 1520. Therefore, a user may see virtual images of images on the first display device 10_2 magnified by the first optical member 1510 through the first eyepiece 1210, and virtual images of images on the second display device 10_3 magnified by the second optical member 1520 through the second eyepiece 1220.

The head strap band 1300 may fix the display device housing 1100 to the user's head so that the first eyepiece 1210 and the second eyepiece 1220 of the housing cover 1200 remain in line with the user's left and right eyes, respectively. By implementing a light and small display device housing 1100, the head-mounted display device 1000_2 may include an eyeglasses frame as shown in FIG. 28 instead of the head strap band 1300.

The head-mounted display device 1000_2 may further include a battery for supplying power, an external memory slot for inserting an external memory, and an external connection port and a wireless communication module for receiving an image source. The external connection port may be a USB (universe serial bus) terminal, a display port, or an HDMI (high-definition multimedia interface) terminal. The wireless communication module may be a 5G communication module, a 4G communication module, a Wi-Fi module, or a Bluetooth module.

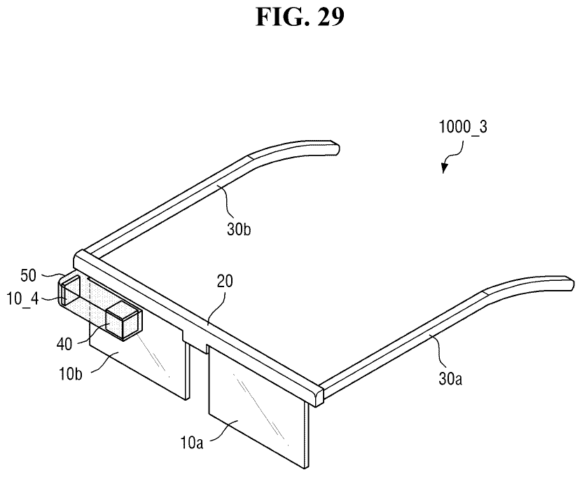

FIG. 29 is a schematic view showing an example of a head-mounted display device including a display device according to an embodiment.

Referring to FIG. 28, a head-mounted display device 1000_3 according to the embodiment may be a device in the form of glasses, and may be a virtual reality device or an augmented reality device. The head-mounted display device 1000_3 according to the embodiment of the disclosure may include a display device 10_4, a left eye lens 10a, a right eye lens 10b, a support frame 20, eyeglass temples 30a and 30b, a reflective member 40, and a display case 50.

Although the head-mounted display device 1000_3 is a glasses-type display device including the eyeglass temples 30a and 30b, the embodiments of the disclosure are not limited thereto. For example, the head-mounted display device 1000_3 may be applied in various forms to other electronic devices.

The display case 50 may include the display device 10_4 and the reflective member 40 (or an optical path conversion member). An image displayed on the display device 10_4 may be reflected by the reflective member 40 and provided to the user's right eye through the right eye lens 10b. Accordingly, the user may watch a virtual reality image displayed on the display device 10_4 through the right eye. For example, the user may see, with the right eye, augmented reality images that combine virtual images displayed on the display device 10_4 and real world images viewed through the right eye lens 10b.

Although the display case 50 is disposed at the right end of the support frame 20 as depicted in FIG. 28, the embodiments of the disclosure are not limited thereto. For example, the display case 50 may be disposed at the left end of the support frame 20. For example, an image displayed on the display device 10_4 may be reflected by the reflective member 40 and provided to the user's left eye through the left eye lens 10a. Accordingly, the user may watch a virtual reality image displayed on the display device 10_4 through the left eye. In another example, the display case 50 may be disposed at both the left and right ends of the support frame 20, respectively. For example, the user may watch a virtual reality image displayed on the display device 10_4 through both the left and right eyes.

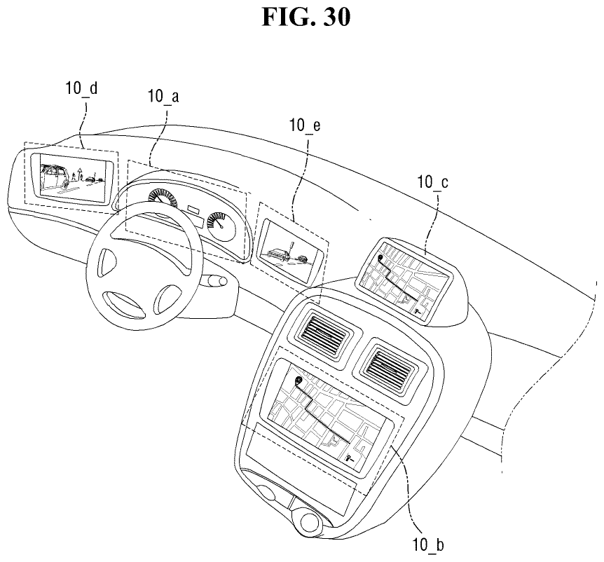

FIG. 30 is a schematic view showing an example of an instrument cluster and a center fascia for a vehicle which include display devices according to an embodiment. FIG. 30 shows a vehicle in which display devices 10_a, 10_b, 10_c, 10_d, and 10_e according to an embodiment are applied.

Referring to FIG. 30, the display devices 10_a, 10_b, and 10_c according to the embodiment of the disclosure may be applied to the instrument cluster of a vehicle, may be applied to the center fascia of the vehicle, or may be applied to a center information display (CID) disposed on the dashboard of the vehicle. The display devices 10_d and 10_e according to the embodiment of the disclosure may be applied to room mirror displays which replace side mirrors of the vehicle.

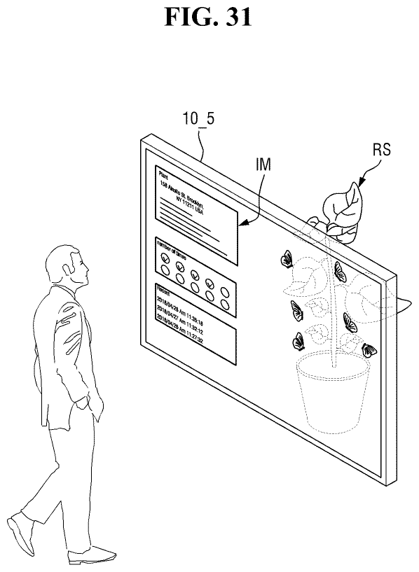

FIG. 31 is a schematic view showing an example of a transparent display device including a display device according to an embodiment.

Referring to FIG. 31, a display device 10_5 according to an embodiment may be applied to a transparent display device. The transparent display device may transmit light while displaying images IM. Therefore, a user located on the front side of the transparent display device may not only watch the images IM displayed on the display device 10_5 but also watch an object RS or the background located on the rear side of the transparent display device. In case that the display device 10_5 is applied to the transparent display device, the substrate of the display device 10_5 may include a light-transmitting portion that transmits light or may be made of a material that transmits light.

At least one of the display devices 10_1, 10_2, 10_3, 10_4, 10_5, 10_a, 10_b, 10_c, 10_d, and 10_e according to the embodiments of FIGS. 25 to 30 may be the display device to which at least one of the embodiments described above is applied (for example, the display device 10 of FIG. 1). For example, at least one of the display devices 10_1, 10_2, 10_3, 10_4, 10_5, 10_a, 10_b, 10_c, 10_d, and 10_e according to the embodiments of FIGS. 25 to 30 may include the capping film CPL covering the side surfaces of the reflective layer RMTL.

In concluding the detailed description, those skilled in the art will appreciate that many variations and modifications may be made to the embodiments without substantially departing from the principles of the disclosure. Therefore, the disclosed embodiments of the invention are used in a generic and descriptive sense only and not for purposes of limitation.

What is claimed is:

1. A display device comprising:
a lower substrate;
a bonding electrode disposed on the lower substrate;
a reflective electrode disposed on the bonding electrode; and
a light-emitting element disposed on the reflective electrode,
wherein the reflective electrode includes:
a reflective layer disposed between the bonding electrode and the light-emitting element and having a shape corresponding to a shape of the light-emitting element in a plan view; and
a capping film covering a side surface of the reflective layer.

2. The display device of claim 1, wherein the capping film is disposed along a border of the reflective layer and covers the side surface of the reflective layer.

3. The display device of claim 1, wherein the reflective layer includes aluminum, and the capping film includes aluminum oxide.

4. The display device of claim 1, wherein the bonding electrode has a size larger than a size of the reflective electrode in the plan view and protrudes outward from the reflective electrode.

5. The display device of claim 4, wherein the bonding electrode has a cross section in an inverted taper shape.

6. The display device of claim 1, wherein the bonding electrode includes: a bonding layer having a bonding metal; a first barrier layer covering a lower surface of the bonding layer; and a second barrier layer covering an upper surface of the bonding layer.

7. The display device of claim 6, wherein the second barrier layer has a size larger than a size of the bonding layer in the plan view and protrudes outward from the bonding layer.

8. The display device of claim 6, further comprising:
an auxiliary layer disposed between the bonding electrode and the reflective electrode,
wherein the auxiliary layer has a size larger than a size of the bonding layer in the plan view and protrudes outward from the bonding layer.

9. The display device of claim 1, further comprising:
a protective film covering a side surface of the light-emitting element and a side surface of the reflective electrode,
wherein the protective film exposes a side surface of the bonding electrode.

10. The display device of claim 1, further comprising:
a second contact electrode disposed on the light-emitting element;
a first insulating layer disposed on the second contact electrode and including an opening exposing at least a portion of the second contact electrode; and
a common electrode disposed on the first insulating layer and electrically connected to the second contact electrode.

11. A method for fabricating a display device, the method comprising:
preparing a first substrate including a semiconductor circuit board and a first bonding material layer disposed on the semiconductor circuit board;
preparing a second substrate including a semiconductor substrate, and an epi-layer, a reflective material layer, and a second bonding material layer sequentially disposed on the semiconductor substrate in a thickness direction;
bonding the first bonding material layer with the second bonding material layer to form a bonding layer;
separating the semiconductor substrate from the epi-layer and forming a first insulating material layer on the epi-layer;
etching the first insulating material layer to form a first insulating layer;
forming a light-emitting element and a reflective layer by etching the epi-layer and the reflective material layer;
forming a capping film covering a side surface of the reflective layer;
forming a protective film covering the bonding layer, the capping film, and the light-emitting element;
etching the protective film and the bonding layer; and
forming a common electrode on the light-emitting element.

12. The method of claim 11, wherein the forming the capping film includes forming an oxide film on a side surface of the reflective layer exposed by etching the reflective material layer.

13. An electronic device comprising:
a lower substrate;
a bonding electrode disposed on the lower substrate;
a reflective electrode disposed on the bonding electrode; and
a light-emitting element disposed on the reflective electrode,
wherein the reflective electrode includes:
a reflective layer disposed between the bonding electrode and the light-emitting element and having a shape corresponding to a shape of the light-emitting element in a plan view; and
a capping film covering a side surface of the reflective layer.

14. The electronic device of claim 13, wherein the capping film is disposed along a border of the reflective layer and completely covers the side surface of the reflective layer.

15. The electronic device of claim 13, wherein the reflective layer includes aluminum, and the capping film includes aluminum oxide.

16. The electronic device of claim 13, wherein the bonding electrode has a size larger than a size of the reflective electrode in the plan view and protrudes outward from the reflective electrode.

17. The electronic device of claim 16, wherein the bonding electrode has a cross section in an inverted taper shape.

18. The electronic device of claim 13, wherein the bonding electrode includes a bonding layer having a bonding metal; a first barrier layer covering a lower surface of the bonding layer; and a second barrier layer covering an upper surface of the bonding layer.

19. The electronic device of claim 18, wherein the bonding layer includes an alloy of gold and tin.

20. The electronic device of claim 18, wherein the second barrier layer has a size larger than a size of the bonding layer in the plan view and protrudes outward from the bonding layer.
